(19) United States
(12) Patent Application Publication
(10) Pub. No.: US 2026/0267177 A1
(43) Pub. Date: Sep. 10, 2026

(54) TRIPLY RESONANT ELECTRO-OPTIC TRANSDUCERS

(71) Applicant: International Business Machines Corporation, Armonk, NY (US)

(72) Inventors: Charles Möhl, Zurich (CH); Paul F. Seidler, Thalwil (CH); Alberto Nardi, Glattpark (CH); Davide Pittilini, Toronto (CA)

(21) Appl. No.: 19/071,913

(22) Filed: Mar. 6, 2025

(51) Int. Cl. G02F 1/035; G02F 1/313; H10N 60/80; H10N 60/81

(52) U.S. Cl. CPC G02F 1/0356; G02F 1/3134; H10N 60/805; H10N 60/815; G02F 2201/063; G02F 2202/32

(57) ABSTRACT

A device includes an electro-optic transducer which comprises a microwave resonator, and an optical transmission line. The microwave resonator comprises a first electrode pad and a second electrode pad separated by a gap. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator.

### BACKGROUND

This disclosure relates generally to triply resonant electro-optic transducers for classical applications and for quantum computing applications. A quantum computing system can be implemented using superconducting circuit quantum electrodynamics (cQED) architectures that are constructed using quantum circuit components such as, e.g., quantum bits (qubits) and other types of superconducting quantum devices that are controlled using, e.g., microwave signals. Various types of quantum information processing algorithms can be implemented using a superconducting quantum processor (or quantum processing unit (QPU)) which comprises superconducting qubits that can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits.

To scale a quantum computing infrastructure, quantum communication between distant quantum computing units (e.g., superconducting quantum processors) over very large distances (e.g., kilometer-scale distances) will be needed. Such long-range quantum links can arguably only be realized in the optical domain. Since many qubit systems operate in the GHz domain, a quantum modem or quantum transducer device can be utilized to convert the GHz qubit signals into, e.g., 200 THz optical signals, much like today's network cards in large datacenters. Such quantum transducers should be designed to enable entanglement between microwave and optical domains with high fidelity.

### SUMMARY

Exemplary embodiments of the disclosure include electro-optic transducers and techniques for implementing electro-optic transducers (or quantum transducers) to enable optical communication between quantum computing systems.

For example, an exemplary embodiment includes a device which comprises an electro-optic transducer. The electro-optic transducer comprises a microwave resonator, and an optical transmission line. The microwave resonator comprises a first electrode pad and a second electrode pad separated by a gap. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator.

Another exemplary embodiment includes a device which comprises an electro-optic transducer. The electro-optic transducer comprises a microwave resonator, and optical transmission line. The microwave resonator comprises a first electrode pad, a second electrode pad, a third electrode pad, and an inductive element. The second electrode pad and the third electrode pad are aligned to each other and separated from the first electrode pad by a gap. The inductive element is connected to and between the second electrode pad and the third electrode pad. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator.

Another exemplary embodiment includes a device which comprises a quantum processor and a control system. The control system is configured to control operation of the quantum processor. The control system comprises at least one electro-optic transducer. The at least one electro-optic transducer comprises a microwave resonator, and an optical transmission line. The microwave resonator comprises a first electrode pad and a second electrode pad separated by a gap. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator. The at least one electro-optic transducer is configured to (i) convert a microwave signal, which is output from the quantum processor, to an optical signal that is transmitted over an optical communications network, and to (ii) convert an optical signal, which is received from the optical communications network, into a microwave signal that is input to the quantum processor.

Other embodiments will be described in the following detailed description of exemplary embodiments, which is to be read in conjunction with the accompanying figures.

### BRIEF DESCRIPTION OF THE DRAWINGS

FIG. 1 schematically illustrates a quantum communications network, according to an exemplary embodiment of the disclosure.

FIG. 2 is a frequency domain plot that graphically illustrates a triply resonant condition which is generated by operation of an electro-optic transducer device, according to an exemplary embodiment of the disclosure.

FIGS. 3A, 3B, and 3C schematically illustrate an electro-optic transducer device, according to an exemplary embodiment of the disclosure.

FIG. 3D schematically illustrates an electro-optic transducer device, according to another exemplary embodiment of the disclosure.

FIG. 3E graphically illustrates exemplary modes of the electro-optic transducer device of FIGS. 3A-3C.

FIG. 4A schematically illustrates an electro-optic transducer device, according to another exemplary embodiment of the disclosure.

FIG. 4B graphically illustrates exemplary modes of the electro-optic transducer device of FIG. 4A.

FIG. 5A schematically illustrates an electro-optic transducer device, according to another exemplary embodiment of the disclosure.

FIG. 5B schematically illustrates an electro-optic transducer device, according to another exemplary embodiment of the disclosure.

FIG. 5C schematically illustrates an electro-optic transducer device, according to another exemplary embodiment of the disclosure.

FIG. 5D graphically illustrates exemplary modes of electro-optic transducer devices according to other exemplary embodiments of the disclosure.

FIG. 6 schematically illustrates an optical resonator of an electro-optic transducer device, which comprises optical resonator portions that are adiabatically coupled, according to an exemplary embodiment of the disclosure.

FIG. 7A schematically illustrates a method for coupling optical signals to and from an optical resonator of an electro-optic transducer device using an optical directional coupler, according to an exemplary embodiment of the disclosure.

FIG. 7B schematically illustrates a method for coupling optical signals to and from an optical resonator of an electro-optic transducer device using an optical directional coupler, according to another exemplary embodiment of the disclosure.

FIG. 8A schematically illustrates photonic crystal mirrors with elliptical holes, which can be used to implement electro-optic transducer devices, according to exemplary embodiments of the disclosure.

FIG. 8B schematically illustrates photonic crystal mirrors with rectangular holes, which can be used to implement electro-optic transducer devices, according to exemplary embodiments of the disclosure.

FIG. 8C schematically illustrates photonic crystal mirrors with crenulations, which can be used to implement electro-optic transducer devices, according to exemplary embodiments of the disclosure.

FIG. 8D schematically illustrates photonic crystal mirrors with pillar structures, which can be used to implement electro-optic transducer devices, according to exemplary embodiments of the disclosure.

FIG. 8E schematically illustrates Sagnac loop mirrors, which can be used to implement electro-optic transducer devices, according to exemplary embodiments of the disclosure.

FIG. 9A schematically illustrates a method for capacitively coupling RF input/output signals to/from an electro-optic transducer device, according to an exemplary embodiment of the disclosure.

FIG. 9B schematically illustrates a method for capacitively coupling RF input/output signals to/from an electro-optic transducer device, according to another exemplary embodiment of the disclosure.

FIG. 9C schematically illustrates a method for galvanically coupling RF input/output signals to/from an electro-optic transducer device, according to another exemplary embodiment of the disclosure.

FIG. 9D schematically illustrates a method for capacitively coupling RF input/output signals to/from an electro-optic transducer device, according to another exemplary embodiment of the disclosure.

FIG. 10 schematically illustrates an electro-optic transducer device, according to another exemplary embodiment of the disclosure.

FIG. 11 schematically illustrates an electro-optic transducer device, according to another exemplary embodiment of the disclosure.

FIG. 12 schematically illustrates an electro-optic transducer device, according to another exemplary embodiment of the disclosure.

FIG. 13 schematically illustrates an electro-optic transducer device, according to another exemplary embodiment of the disclosure.

FIG. 14 schematically illustrates an electro-optic transducer device, according to another exemplary embodiment of the disclosure.

FIG. 15 schematically illustrates an electro-optic transducer device, according to another exemplary embodiment of the disclosure.

FIG. 16 schematically illustrates an electro-optic transducer device, according to another exemplary embodiment of the disclosure.

FIG. 17 schematically illustrates an electro-optic transducer device, according to another exemplary embodiment of the disclosure.

FIG. 18 schematically illustrates a quantum computing system which implements electro-optic transducers to enable optical communication with remote quantum computing systems, according to an exemplary embodiment of the disclosure.

FIG. 19 schematically illustrates an exemplary architecture of a computing environment for hosting a quantum computing platform and performing quantum information processing, according to an exemplary embodiment of the disclosure.

### DETAILED DESCRIPTION

Exemplary embodiments of the disclosure will now be described in further detail with regard to electro-optic transducers (e.g., triply resonant electro-optic transducers), and techniques for implementing electro-optic transducers (or quantum transducers) for optical communication between quantum computing systems. In general, exemplary triply resonant electro-optic (EO) transducers as discussed herein comprise integrated EO transducer devices, which co-integrate on-chip microwave circuits and metal electrodes with optical integrated circuits made from a material with a χ⁽²⁾-non-linearity at gigahertz (GHz) frequencies, so called Pockels materials. The electro-optic effect (or EO effect) is a phenomenon in which the refractive index of a material changes in response to an applied electric field, where the electro-optic effect modulates the optical properties of the material. The electro-optic effect encompasses a number of distinct phenomena, which include a change of the refractive index and permittivity. For example, the Pockels effect (or linear electro-optic effect) denotes a change in the refractive index linearly proportional to the electric field. The Pockels effect parametrically couples DC and RF fields in a microwave resonator circuit to optical signals in an optical resonator waveguide. Due to strict requirements for the transduction of quantum signals in terms of added noise and efficiency, it is advantageous to resonantly enhance the optical and microwave signals by designing an EO transducer to host resonant modes for the optical signal, the microwave signal, as well as the optical carrier signal (referred to herein as optical pump signal), wherein the EO quantum transducers are designed to be triply resonant.

Designing a triply resonant EO transducer is not trivial, especially for high-Pockels-effect materials such as LiNbO₃, BaTiO₃ or for cryogenic temperatures SrTiO₃, since the group indices of the electrical/microwave signal n_{RF} and optical signal n_{g,opt} are usually mismatched, referred to as “phase mismatch.” This stems from the fact that, while an effective optical group index in all these materials is about 2, the electrical permittivity (that is, the permittivity from DC to tens or hundreds of GHz) generally increases with an increase in the Pockels coefficient of the material. For example, for industry standard LiNbO₃ material, the permittivity is about ϵ_{r,LiNb03}=30, which corresponds to a refractive index at GHz frequencies of 5.7 according to n=\sqrt{ϵᵣμᵣ}, and μᵣ=1. In an integrated device, where the microwave field only overlaps partially with the active material, this leads to a moderate mismatch of the electrical and optical group indices, which can in some cases be compensated by design optimization. For next-generation large-Pockels-effect materials such as BaTiO₃ and SrTiO₃, with permittivities of up to ϵ_{r,BaTiO3}=10³ and ϵ_{r,SrTiO3}=104 at their optimal operations points, this mismatch can get very large, and more and more difficult to compensate.

In this regard, it is typically challenging to fabricate, at scale and reproducibly, triply resonant EO transducers due to tight fabrication tolerances, to achieve desired energy matching. In addition, triply resonant EO transducers are difficult to engineer due to complex coupling of optimization parameters of the system (ring radius, ring-ring-/bus-coupling rate, etc.) and have limited range of reachable system parameters required for, e.g., very-large-permittivity or high-kinetic inductance microwave circuits. In addition, conventional triply resonant EO transducers are typically bulky and have large footprints, do not provide maximized mode overlap, and do not provide meaningful phase/frequency-matching design tunability.

The drawbacks of existing solutions for triply resonant EO transducers (e.g., large ring/racetrack EO transducers, or photonic-molecule EO transducers) are generally the design/fabrication challenges stemming from the fact that triply resonant EO transducers are based on large, closed ring structures and directional couplers, as well as inherent design trade-offs between electrode coverage, bending losses, fabrication tolerances and phase mismatch for very high permittivity or kinetic inductance microwave circuits. If the phase mismatch between optical signals and microwave signals is significant, a photonic molecule EO transducer is a viable option. However, a double-ring structure of a photonic molecule EO transducer based on coupled optical ring resonators imposes a high level of fabrication complexity by requiring almost always to bridge superconducting connections across optical waveguides. Moreover, ring EO transducers typically have a relatively large footprint, which is limited by (i) the minimum radius to perform an adiabatic direction change of 180 degrees, and (ii) by the fact, that a traveling-wave system (such as ring resonators) needs double the waveguide length compared to that of a standing wave resonator.

Moreover, in order to maximize electrode coverage along an optimum crystal direction of the photonic material, bent sections of resonators need to be minimized, meaning that in a racetrack EO structure, the length of the straight sections should be maximized. In order to have adiabatic bends, the radius of curvature should be sufficiently large, and the transition from straight to bent section should be fairly slow. In practice, this means that very long racetrack resonators must be designed. However, this leads to a fairly low free spectral range (FSR), which again makes matching to large microwave frequencies almost impossible. An increase in the ring-ring coupling rate (of a photonic-molecule EO transducer device) would be challenging, as this would likely require a reduction in the optical confinement, which would have negative implications on the bending losses and adiabaticity of the entire EO transduction system.

Again, a problem with the photonic molecule based on ring structures is that the coupling rate between the ring structures is limited by the achievable power splitting ratio at the ring-ring coupling point. Reducing the confinement by reducing a ridge height of the optical waveguide leads to increased bending losses and mode mixing, but using tighter gaps makes the fabrication tolerances even more demanding. In addition, one cannot freely choose the ideal ridge/slab height that would be optimal for EO modulation in straight waveguide sections. Again, in practice, this limits the achievable microwave frequency range.

With regard to crystal orientation, in most cases, the Pockels effect is orientation dependent, meaning that there usually is one orientation of the waveguide on the chip for optimum modulation. In a ring structure, however, one always has sections of the resonator that do not align with this optimum direction. Depending on the angle dependence of the effective EO effect, this can mean that only a small fraction of the resonator waveguide is actually aligned with the optimum direction.

Exemplary embodiments of the disclosure include various triply resonant EO transducer architectures which, as explained in further detail below, eliminate the use of ring-based triply resonant EO transducer structures and the disadvantage and limitations associated therewith. For example, an exemplary embodiment includes a device which comprises an electro-optic transducer. The electro-optic transducer comprises a microwave resonator, and an optical transmission line. The microwave resonator comprises a first electrode pad and a second electrode pad separated by a gap. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator.

Another exemplary embodiment includes a device which comprises an electro-optic transducer. The electro-optic transducer comprises a microwave resonator, and optical transmission line. The microwave resonator comprises a first electrode pad, a second electrode pad, a third electrode pad, and an inductive element. The second electrode pad and the third electrode pad are aligned to each other and separated from the first electrode pad by a gap. The inductive element is connected to and between the second electrode pad and the third electrode pad. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator.

Another exemplary embodiment includes a device which comprises a quantum processor and a control system. The quantum processor comprises an array of quantum bits. The control system is configured to control operation of the quantum processor. The control system comprises at least one electro-optic transducer. The electro-optic transducer comprises a microwave resonator and an optical transmission line. The microwave resonator comprises a first electrode pad and a second electrode pad separated by a gap. The optical transmission line comprises an optical resonator, a first photonic mirror, a second photonic mirror, and a third photonic mirror. The optical resonator is disposed within the gap between the first electrode pad and the second electrode pad. The first photonic mirror is disposed at a first end of the optical resonator. The second photonic mirror is disposed at a second end of the optical resonator. The third photonic mirror is disposed in a central region of the optical resonator. The electro-optic transducer is configured to convert a microwave signal, which is readout from at least one quantum bit of the quantum processor, to an optical signal that is transmitted over an optical communications network. The electro-optic transducer is configured to convert an optical signal, which is received from the optical communications network, into a microwave signal that is utilized to change a state of the at least one quantum bit.

In another exemplary embodiment, which may be combined with one or more of the embodiments of the preceding paragraphs, the electro-optic transducer comprises a triply resonant electro-optic transducer which is configured to generate optical resonant modes for an optical signal and an optical carrier signal, and to generate a microwave resonant mode for a microwave signal. The third photonic mirror disposed in the central region of the optical resonator comprises a reflection property that is configured to shift a phase of the optical resonant modes to enable phase matching between the microwave resonant mode and the optical resonant modes.

In another exemplary embodiment, which may be combined with one or more of the embodiments of the preceding paragraphs, the microwave resonator comprises an open-ended coplanar microstrip resonator.

In another exemplary embodiment, which may be combined with one or more of the embodiments of the preceding paragraphs, the first photonic mirror comprises a partially reflective mirror, the second photonic mirror comprises a fully reflective mirror, and the third photonic mirror comprises a partially reflective mirror.

In another exemplary embodiment, which may be combined with one or more of the embodiments of the preceding paragraphs, the first photonic mirror, the second photonic mirror, and the third photonic mirror comprise respective patterns of photonic crystal structures formed in the optical transmission line, the photonic crystal structures comprising at least one of holes, crenulations, and pillar structures.

In another exemplary embodiment, which may be combined with one or more of the embodiments of the preceding paragraphs, the optical resonator comprises a ridge waveguide structure comprising a first lateral extension connected to the first electrode pad, and a second lateral extension connected to the second electrode pad.

In another exemplary embodiment, which may be combined with one or more of the embodiments of the preceding paragraphs, the microwave resonator and the optical resonator have respective physical lengths that are substantially equal.

In another exemplary embodiment, which may be combined with one or more of the embodiments of the preceding paragraphs, the optical transmission line is configured to enable input and output of the optical signal and the optical carrier signal to and from the optical resonator through the first photonic mirror.

In another exemplary embodiment, which may be combined with one or more of the embodiments of the preceding paragraphs, the device further includes a second optical transmission line which comprises a directional coupler that is configured to enable input and output of the optical signal and the optical carrier signal to and from the optical resonator.

In another exemplary embodiment, which may be combined with one or more of the embodiments of the preceding paragraphs, the inductive element of the opto-electric device has a voltage-tunable inductance or a magnetic flux-tunable inductance.

In another exemplary embodiment, which may be combined with one or more of the embodiments of the preceding paragraphs, the inductive element comprises a direct-current superconducting quantum interference device.

In another exemplary embodiment, which may be combined with one or more of the embodiments of the preceding paragraphs, the inductive element comprises one of a surface mount inductor device, and an integrated planar inductor element.

In another exemplary embodiment, which may be combined with one or more of the embodiments of the preceding paragraphs, the device further comprises at least one tuning electrode coupled to a portion of the optical resonator, and configured to apply a tuning voltage to the portion of the optical resonator to tune an optical resonant frequency of the optical resonator.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

To provide spatial context to the different structural orientations of structures shown throughout the drawings, XYZ Cartesian coordinates are shown in some drawings. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings. In the exemplary illustrations, the Z-direction represents a line that is normal to a plane of a substate on which devices are fabricated, and the X-direction and Y-direction represent lines that are parallel to the plane of the substrate.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, tunable couplers, quantum control circuitry, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the term “quantum chip” as used herein refers to a die (e.g., semiconductor die) which comprises superconducting integrated circuitry comprising various superconducting components such as qubits, tunable couplers, ground planes, signal coplanar waveguides, resonators, etc. A plurality of dies having the same and/or different configurations of superconducting electronic integrated circuits, can be fabricated on a wafter (e.g., semiconductor wafer), wherein the individual dies can be diced (cut) from the wafer using a die singulation process to provide singulated dies which can be packaged together to construct a modular quantum processor architecture.

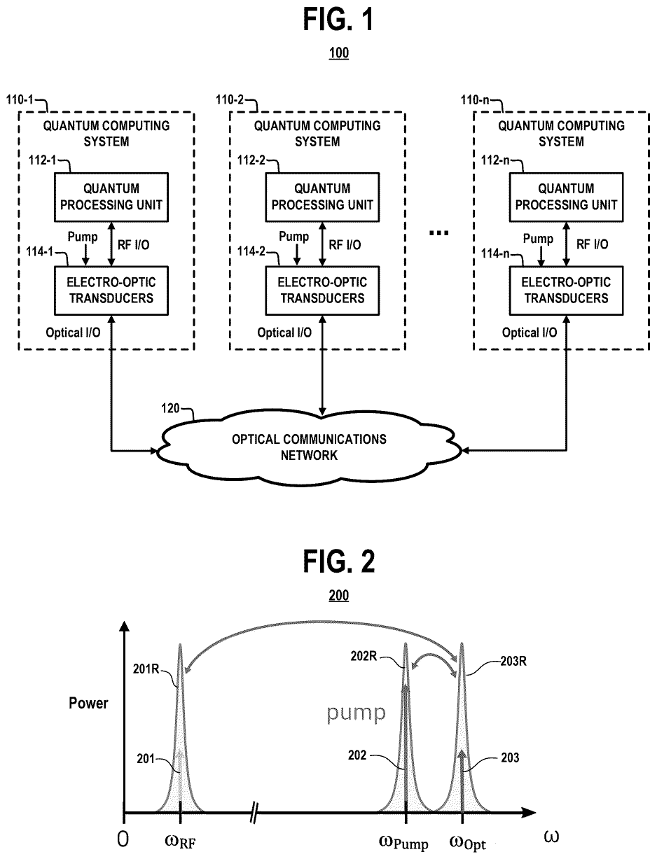

FIG. 1 schematically illustrates a quantum communications network, according to an exemplary embodiment of the disclosure. In particular, FIG. 1 schematically illustrates a quantum communications network 100 which comprises a plurality of quantum computing systems 110-1, 110-2, . . . , 110-n (collectively, quantum computing systems 110) which communicate over an optical communications network 120. The optical communications network 120 can be implemented using any suitable fiber-optic network architecture comprising optical fibers to transmit optical signals (which are modulated by quantum signals) between the quantum computing systems 110, and other optical and/or optoelectronic components such as repeaters, splitters, amplifiers, multiplexers/demultiplexers to support, e.g., wavelength-division multiplexing (WDM), etc.

The quantum computing systems 110-1, 110-2, . . . , 110-n comprise respective quantum processing units 112-1, 112-2, . . . , 112-n (collectively, quantum processing units 112), and respective electro-optic (EO) transducers 114-1, 114-2, . . . , 114-n (collectively, EO transducers 114). In some embodiments, the quantum processing units 112-1, 112-2, . . . , 112-n each comprise one or more quantum chips which comprise computational quantum bits (qubits) to perform quantum computations, as well as readout resonators and multiple layers of wiring for input/output (I/O). In addition, the quantum processing units 112-1, 112-2, . . . , 112-n each comprise control electronics and classical compute hardware to perform various functions, such as generating control signals, amplifying signals, filtering, and managing I/O signals, etc. The quantum chips are maintained in cryogenic environments (e.g., near absolute zero) in, e.g., a multi-stage dilution refrigerator or cryostat. The control electronics include components that reside inside a multi-stage dilution refrigerator, and other components that reside in a room temperature environment beside the dilution refrigerators.

In general, the EO transducers 114-1, 114-2, . . . , 114-n are configured to perform RF-optical transduction operations to provide interfaces between RF and optical domains of the quantum computing systems 110 and optical communications network 120 and, thereby, enable communication between the quantum computing systems 110 over the optical communications network 120. In particular, the EO transducers 114-1, 114-2, . . . , 114-n are configured to convert RF signals (which are generated by the quantum processing units 112) to optical signals that are transmitted over the optical communications network 120. In addition, the EO transducers 114-1, 114-2, . . . , 114-n are configured to convert optical signals, which are received over the optical communications network 120, into RF signals that are input to the quantum processing units 112. The number of EO transducers that are implemented in each of the quantum computing systems 110 will vary depending on the system architecture, e.g., the number and arrangement of quantum bits implemented by the quantum processing units 112. For example, in some embodiments, a given quantum computing system can have one EO transducer per quantum bit, while in other embodiments, a given quantum computing system can groups of quantum bits that share a given EO transducer in a multiplexed configuration. For example, the readout resonators of a plurality of quantum bits can be coupled to one EO transducer which is configured to convert the readout state of the plurality of quantum bits to optical signals, in a multiplexed manner, for transmission over the optical communications network 120.

In accordance with exemplary embodiments discussed in further detail below, the EO transducers 114-1, 114-2, . . . , 114-n are implemented using integrated (on-chip) triply resonant EO transducer architectures for RF-optical transduction. The exemplary EO transducer architectures comprise integrated RF and optical resonators, which are configured to provide efficient RF-optical conversion through simultaneous resonant enhancement of an RF signal, and optical signals, and an optical carrier signal (referred to herein as optical pump signal). The optical pump signal can be a continuous-wave (CW) optical signal or a pulsed optical signal. For example, as schematically illustrated in FIG. 1, each EO transducer of the plurality of EO transducers 114 comprises an RF signal I/O port, a Pump signal input port, and an optical signal I/O port. Each EO transducer of the plurality of EO transducers 114 is configured to utilize an optical pump signal (Pump) to (i) convert RF signals (RF input) into optical signals (optical output) for transmission over the optical communications network 120, and (ii) convert optical signals (optical input) received from the optical communications network 120 into RF signals (RF output).

FIG. 2 is a frequency domain plot that graphically illustrates a triply resonant condition which is generated by operation of an EO transducer, according to an exemplary embodiment of the disclosure. In particular, FIG. 2 is a graph 200 that represents signal power (Y-axis) as a function of frequency (in radians ω) for various signals. In particular, FIG. 2 illustrates an RF signal 201 having a frequency ω_{RF}, an optical pump signal 202 (e.g., laser pump signal) having a frequency ωₚᵤₘₚ, and an optical signal 203 having a frequency ω_{Opt}. The RF signal 201, the optical pump signal 202, and the optical signal 203 are graphically illustrated as arrows at a single frequency having respective power levels, wherein the power level of the optical pump signal 202 is greater than the power level of an input RF signal (e.g., RF signal 201) or an input optical signal (e.g., optical signal 203).

Moreover, FIG. 2 graphically illustrates resonator modes including a resonant RF mode 201R, a resonant optical pump mode 202R, and a resonant optical signal mode 203R, which represent microwave and optical resonances of microwave and optical resonators of a triply resonant EO transducer. For a triply resonant condition, the RF signal 201, the optical pump signal 202, and the optical signal 203 have frequencies which correspond approximately to the center frequencies of the microwave and optical resonant modes, i.e., are within the linewidths of the microwave and optical resonant modes. The interaction of the RF signal 201 (input RF signal) and the optical pump signal 202 (when input to a triply resonant EO transducer), results in the generation of a signal within the resonant optical signal mode 203R (output optical signal) with a frequency ω_{Opt} which is shifted in frequency with respect to the optical pump frequency ω_{Pump} according to a triply resonant condition: ω_{RF}=ω_{Opt}−ω_{Pump}, or ω_{Opt}=ω_{RF}+ω_{Pump}.

Moreover, the interaction of the optical signal 203 (input optical signal) and the optical pump signal 202 (when input to the triply resonant EO transducer), results in the generation of an RF signal within the resonant RF mode 201R with the frequency ω_{RF}=ω_{Opt}−ω_{Pump} according to the triply resonant condition. The RF signal 201 and the optical signal 203 have power levels which are increased by the input power of the optical pump signal 202. In an exemplary non-limiting embodiment, the optical pump signal 202 can have a frequency ω_{Pump}/2π~200 terahertz (THz), and the RF signal 201 can have a frequency ω_{RF}/2π~5 gigahertz (GHz).

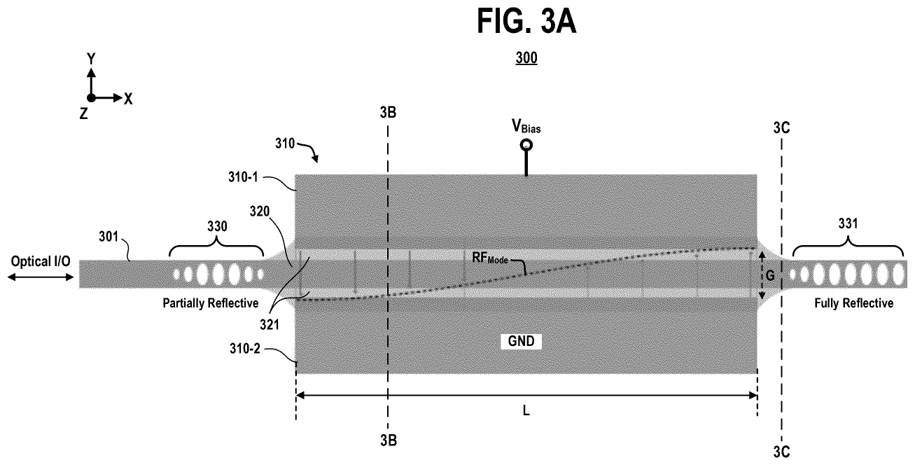

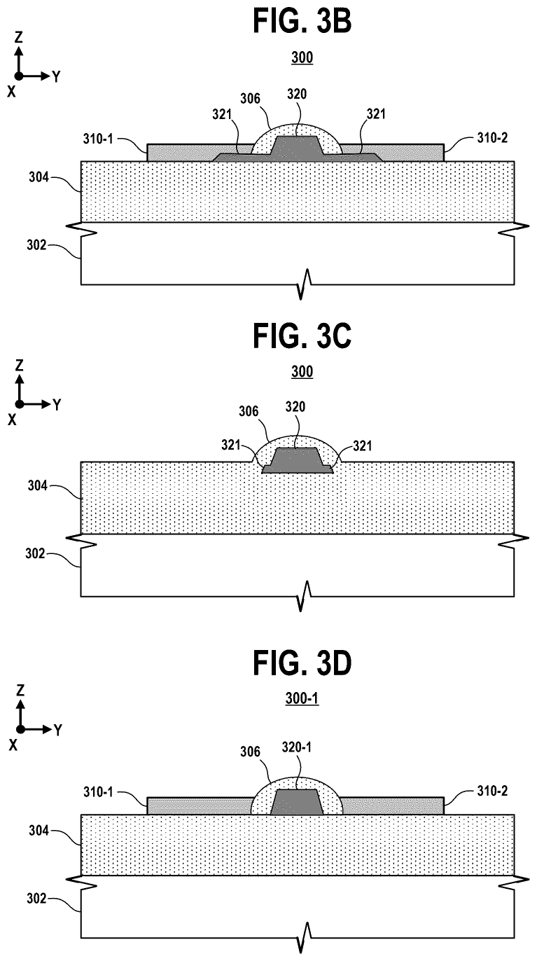

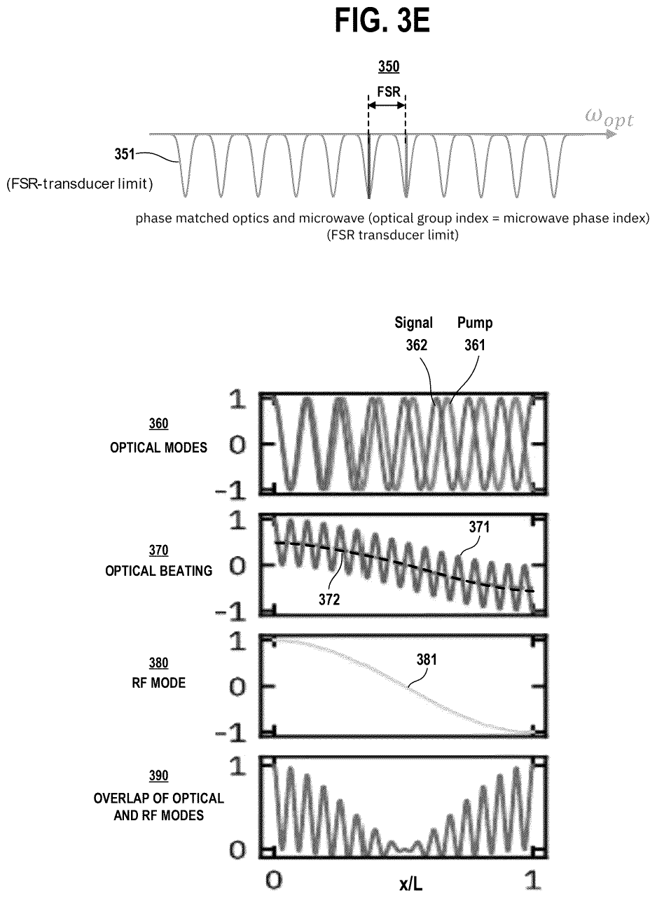

FIGS. 3A, 3B, and 3C schematically illustrate an EO transducer device, according to an exemplary embodiment of the disclosure. In particular, FIG. 3A is a schematic top plan view of an EO transducer 300, FIG. 3B is a schematic cross-sectional view of the EO transducer 300 along line 3B-3B in FIG. 3A, and FIG. 3C is a schematic cross-sectional view of the EO transducer 300 along line 3C-3C in FIG. 3A. In general, the EO transducer 300 comprises a co-integrated hybrid optical/microwave resonator which implements optical and microwave resonators as linear resonators for optical and RF/microwave signals. In particular, the EO transducer 300 comprises an RF resonator 310 and an optical resonator 320.

The RF resonator 310 comprises a first electrode pad 310-1 and a second electrode pad 310-2. The first and second electrode pads 310-1 and 310-2 are metallic electrodes with length L (or length L of RF resonator 310), and are disposed in a co-planar configuration (disposed on same X/Y plane) separated by an electrode gap G (or spacing). The size of the gap G is designed to optimize an efficiency of an optical-RF transduction process. In some embodiments, the ends of the first and second electrode pads 310-1 and 310-2 are open-ended (not shorted), to implement a half-wavelength (λ/2) resonator in which the length L of the RF resonator 310 is designed to be λ/2 of a target RF signal having a fundamental operating frequency ω_{RF} (i.e., L=0.5 λ_{RF}). In this regard, FIG. 3A schematically illustrates an exemplary voltage-wave distribution (denoted RF_{Mode}) of an RF signal (fundamental frequency ω_{RF}) along the length of the RF resonator 310 (open-ended, λ/2 transmission line resonator), in which the RF signal is maximum at the ends of the RF resonator 310, and minimum (zero) at a mid-point of the RF resonator 310. The first and second electrode pads 310-1 and 310-2 can be formed of any type of metal or metallic material which is suitable for the given application. For example, in embodiments where the EO transducer 300 is configured for operation in a cryogenic environment, the first and second electrode pads 310-1 and 310-2 can be formed of a superconducting metal/metallic material having a suitable critical temperature (Tc), such as aluminum (Al), niobium (Nb), tantalum (Ta), titanium (Ti), tungsten (W), tin (Sn), molybdenum (Mo), or nitrides of the same, or combinations thereof, and/or the like.

The optical resonator 320 comprises a portion of an optical transmission line 301 (alternatively, optical waveguide), which is disposed in the gap G region between the first and second electrode pads 310-1 and 310-2 of the RF resonator 310. As further shown in FIG. 3A, the optical transmission line 301 comprises a first photonic crystal mirror 330 and a second photonic crystal mirror 331 disposed at end portions of the optical resonator 320, which are configured to generate optical standing waves of multiple optical wave signals (two of which are of interest) along the optical resonator 320. The first photonic crystal mirror 330 comprises a partially reflective mirror, and the second photonic crystal mirror 331 comprises a fully reflective mirror. In some embodiments, the first and second photonic crystal mirrors 330 and 331 comprise integrated Bragg reflectors that are constructed with elliptical holes that are etched in the optical transmission line 301 at the ends of the optical resonator 320.

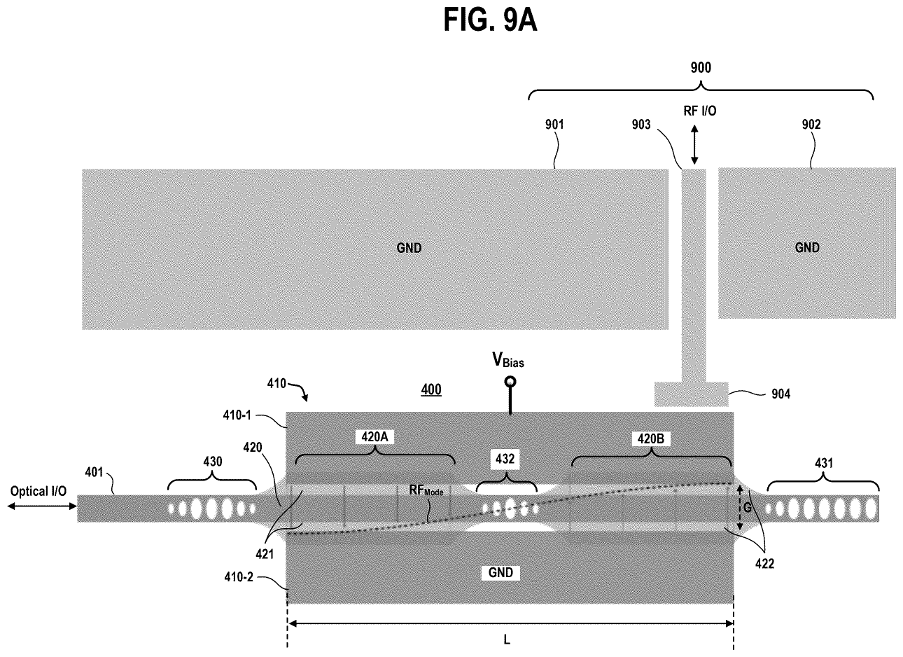

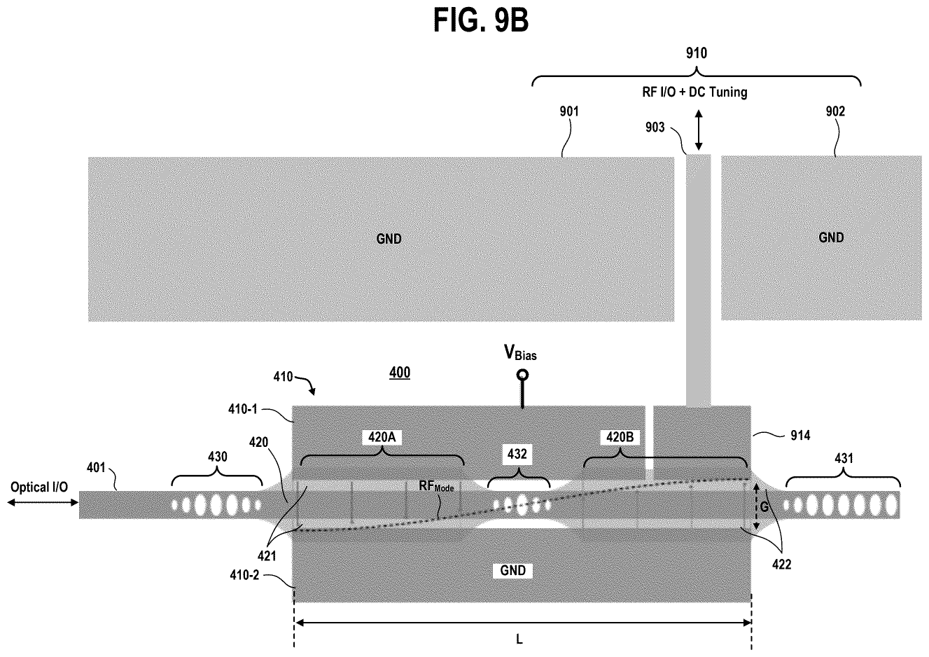

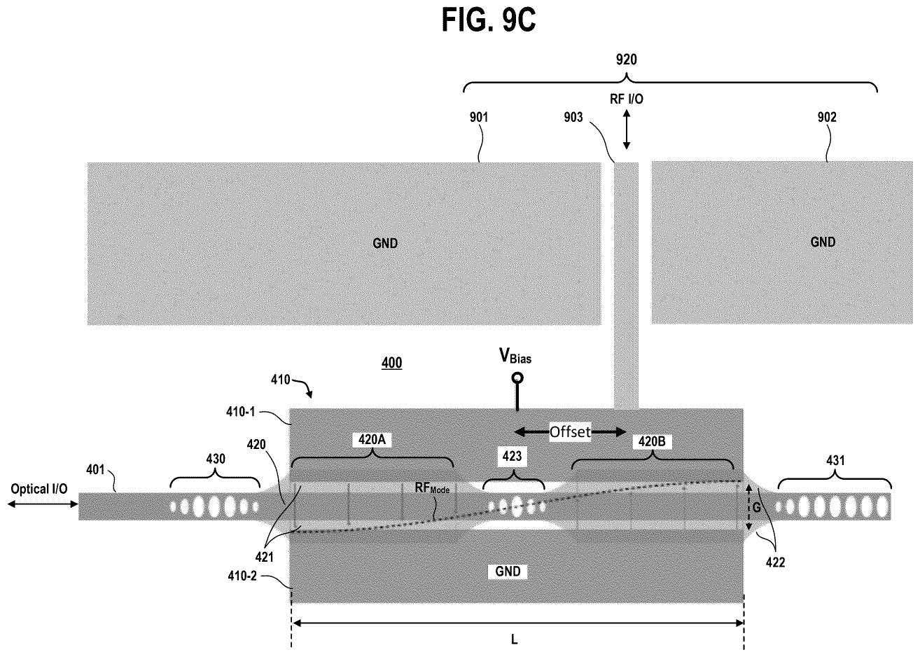

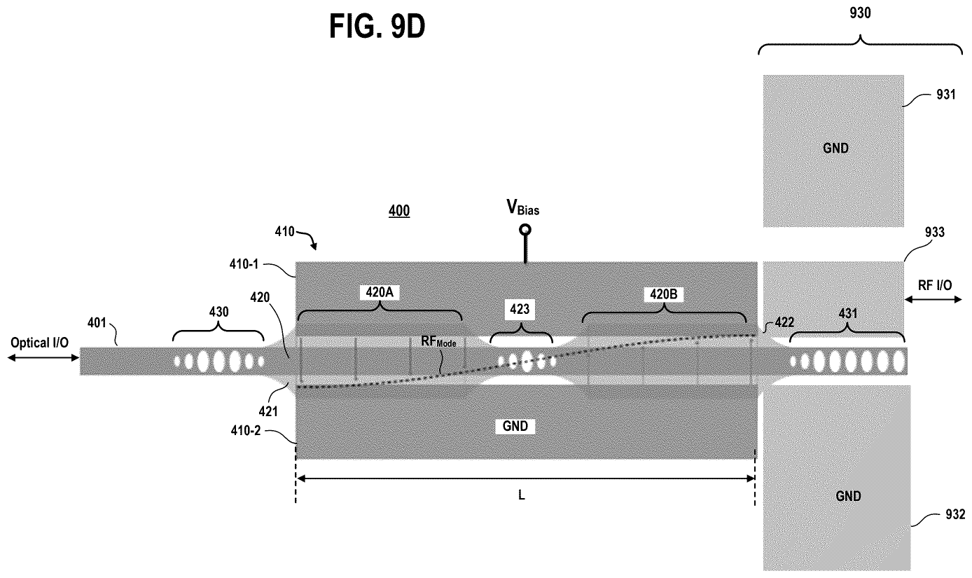

The optical transmission line 301 is configured to (i) transmit and apply optical input signals (e.g., optical pump signal, received optical signal) to one end of the optical resonator 320, which pass through the first photonic crystal mirror 330, and to (ii) receive and transmit an optical signal which is output from the optical resonator 320 through the first photonic crystal mirror 330, depending on the operating mode of the EO transducer 300. For example, when converting an optical signal to an RF signal, the optical signal and optical pump signal are input to the optical resonator 320, which results in forming RF and optical standing waves along the RF resonator 310 and the optical resonator 320 (via a triply resonant mixing operation of the EO transducer 300) which, in turn, results in generating an RF signal that is output from the RF resonator 310. The RF signal is output using coupling mechanisms as discussed below in conjunction with FIGS. 9A-9D).

On the other hand, when converting an RF signal to an optical signal, an RF signal is coupled to the RF resonator 310 and an optical pump signal is input to the optical resonator 320, which results in forming RF and optical standing waves along the RF resonator 310 and the optical resonator 320 (via a triply resonant mixing operation of the EO transducer 300) which, in turn, results in generating an optical signal that is output from the optical resonator 320. The RF signal is coupled to the RF resonator 310 using coupling mechanisms as discussed below in conjunction with FIGS. 9A-9D).

The optical transmission line 301 (and thus the optical resonator 320) is formed of any suitable electro-optic material, such as barium titanate (BaTiO₃). The optical resonator 320 may comprise any suitable channel-type optical waveguide structure. For example, in some embodiments, the optical resonator 320 comprises a ridge waveguide structure which includes lateral extensions 321 that are configured to enable contact between the first and second electrode pads 310-1 and 310-2 (of the RF resonator 310) and the optical resonator 320 disposed in the gap G between the first and second electrode pads 310-1 and 310-2. In some embodiments, the optical resonators of EO transducers are preferably implemented using ridge waveguide structures when the optical resonators are formed of photonic materials with relatively large permittivities (e.g., LiNbO₃, BaTiO₃, SrTiO₃), wherein a ridge waveguide structure allows the first and second electrode pads 310-1 and 310-2 (of the RF resonator 310) to make contact with the EO material of the waveguide core of the optical resonator 320.

Indeed, for high-permittivity EO materials, it is desirable for the electrode pads of the RF resonator 310 to be in contact with the EO material of the waveguide core of the optical resonator 320. In other embodiments, when the optical resonator 320 is formed of an EO material having a relatively low permittivity (e.g., gallium phosphide (GaP), or silicon (Si), etc.), it is desirable for the RF resonator electrodes to be disposed adjacent to the waveguide core of the optical resonator 320, and not directly connected to the waveguide core of the optical resonator 320 (see alternate embodiment of optical resonator 320-1 discussed below in conjunction with FIG. 3D). This comes in general from a trade-off between optical confinement (which is better when the material is not in contact with the electrodes) and microwave field penetration (which is better, if the material is in contact with the electrodes and/or if the material permittivity is sufficiently low).

The ridge-type optical waveguide structure enables direct contact between optical resonator 320 and the first and second electrode pads 310-1 and 310-2 of the RF resonator 310, to thereby allow a DC bias voltage (denoted V_{Bias}) to be applied to one electrode (e.g., the first electrode 310-1) with the other electrode (e.g., second electrode 310-2) DC grounded. The DC bias voltage V_{Bias} is utilized in embodiments where a DC bias voltage needs to be applied to the optical resonator material (e.g., barium titanate) to achieve an electro-optic effect. In an exemplary embodiment, the DC bias voltage V_{Bias} is applied by a DC bias line which is galvanically connected to, e.g., the first electrode pad 310-1 of the RF resonator 310, at a central point of the EO transducer 300 where the electric field amplitude (along the RF resonator 310) is zero (0) or near zero. For example, based on the exemplary voltage distribution of the RF_{Mode} as shown in FIG. 3A, the DC bias voltage V_{Bias} is applied to a contact point of the first electrode pad 310-1 of the RF resonator 310, which contact point is aligned to a center point of the RF resonator 310 where the electric field amplitude is zero (0). In this configuration, the galvanic connection of the DC bias voltage line to the center point of the RF resonator 310 prevents or otherwise substantially minimizes coupling of the RF signal to the DC bias voltage line and thus prevents or minimizes RF losses of the EO transducer 300.

As schematically illustrated in the cross-sectional view of FIG. 3B, the EO transducer 300 comprises a substrate 302, an optical cladding layer 304 disposed on the substrate 302, the optical resonator 320 (optical waveguide resonator) disposed on the optical cladding layer 304, and an optical cladding layer 306 covering upper and sidewall surfaces of the optical resonator 320. As noted above, the optical resonator 320 comprises lateral extensions 321 that are disposed on opposites sides of the optical resonator 320, which are configured to make contact to the first and second electrode pads 310-1 and 310-2 of the RF resonator 310, as shown in FIG. 3B. As schematically illustrated in the top plan view of FIG. 3A, and the cross-sectional view of FIG. 3C, the lateral extensions 321 of the optical resonator 320 taper down and essentially disappear at the end regions of the optical resonator 320 before the first and second photonic crystal mirrors 330 and 331. In FIGS. 3B and 3C, the substrate 302 can be formed of silicon, sapphire, or any other suitable type of substrate material. The optical cladding layers 304 and 306 can be formed of silicon oxide (e.g., silicon dioxide) or other suitable types of optical cladding material. In other embodiments, the optical cladding layer 306 can be omitted in which case the ridge of the optical waveguide of the optical resonator 320 will be surrounded on three sides (top and sidewall surfaces) by air. The optical resonator 320 and lateral extensions 321 can be formed of any suitable photonic crystal material including, but not limited to, high-Pockels-effect materials such as lithium niobate (LiNbO3), barium titanate (BaTiO3), etc., or strontium titanate (SrTiO₃) for cryogenic temperatures, etc.

FIG. 3D schematically illustrates an EO transducer 300-1, according to another exemplary embodiment of the disclosure. The EO transducer 300-1 is similar to the EO transducer 300 of FIGS. 3A-3C, except that FIG. 3D illustrates an exemplary embodiment of an optical resonator 320-1 (waveguide core) having a rib waveguide structure in which the first and second electrode pads 310-1 and 310-2 of the RF resonator 310 are disposed adjacent to the optical resonator 320-1 (waveguide core), and not directly connected to the waveguide core. Again, as noted above, FIG. 3D illustrates an exemplary architecture of an optical waveguide that can be implemented when the optical resonator 320-1 is formed of an EO material (e.g., GaP or Si) having a relatively low permittivity, where the RF resonator electrodes are disposed adjacent to the waveguide core of the optical resonator 320-1, and not directly connected to the waveguide core of the optical resonator 320-1. This configuration provides optical confinement where the waveguide core of the optical resonator 320-1 is surrounded (three sides) by the optical upper optical cladding layer 306 (or air), and the lower optical cladding layer 304.

Essentially, the EO transducer 300 comprises a one-dimensional (1D) linear resonator architecture to realize a compact, small footprint, on-chip triply resonant EO transducer. For both the optical and electrical domains, the optical resonator and the RF resonator can each be viewed as a transmission line that is terminated at both ends with a mirror element, which reflects the waves and leads to the formation of standing-wave resonances. In the optical field, the optical resonator 320 can be considered as a Fabry-Pérot microcavity, while in the RF field, the RF resonator 310 can be considered an open-ended microwave stripline. A basic architecture of the EO transducer 300 comprises a patterned 1D microwave resonator which has an optical resonator disposed within an electrode gap of the microwave resonator, effectively co-integrating the optical and RF resonators to form a hybrid optical/microwave resonator. The mirrors for the RF resonator 310 are realized by the open ends of the electrode pads, while the mirrors for the optical resonator 320 are realized by photonic crystal mirrors.

FIG. 3E graphically illustrates exemplary modes of the EO transducer 300 of FIGS. 3A-3C. For example, FIG. 3E depicts a graph 350 which illustrates an optical transmission spectrum 351 of a Fabry-Pérot resonator with multiple optical resonant standing-wave modes corresponding to multiple resonance dips in the optical transmission spectrum 351 separated by a given optical FSR in frequency, i.e., the FSR represents a spacing or distance in frequency between two successive resonant dips in the optical transmission spectrum 351.

In an ideal case of perfect phase matching, the RF resonator 310 and the optical resonator 320 have equal lengths and thereby maximize the overlap or electrode coverage. In particular, in this ideal case, for energy conservation and triple resonance, the FSR of the optical resonator 320 and the λ/2 resonance frequency ω_{RF} of the RF resonator 310 are equal:

$$FSR = \frac{{c}_{0}}{{n}_{g , opt} \cdot 2 L}$$

$${ω}_{RF} = \frac{{c}_{0}}{{n}_{RF} \cdot 2 L}$$

which implies that the optical group index n_{g,opt} equals the microwave phase index n_{RF}. Here, c₀ is the speed of light in vacuum. If the condition n_{g,opt}=n_{RF} is met, the EO transducer device can be constructed to have equal-length microwave and optical resonators, where the energy matching condition will be met. In this regard, the exemplary EO transducer 300 shown in FIGS. 3A-3C can be considered a linear “FSR-type transducer” with perfect phase/frequency matching and maximum mode overlap. The term “FSR-type transducer” as used refers to a device in which the optical free spectral range (FSR) matches or is close to the target microwave frequency. This is in contrast to the photonic molecule, where the free spectral range is typically significantly larger than the target microwave frequency.

FIG. 3E depicts various graphs 360, 370, 380, and 390, which graphically illustrate modes of a linear triply resonator EO transducer (e.g., EO transducer 300) in the FSR-type transducer regime. In particular, the graph 360 illustrates normalized amplitudes of optical signal modes including an optical pump signal 361 (ω_{Pump}) and an optical signal 362 (ω_{Opt}). The graph 370 illustrates an optical beating signal 371 which results from the combination of the optical resonant standing waves of the optical pump signal 361 and the optical signal 362, as a function of longitudinal position x along the length L of the EO transducer 300. In addition, the graph 370 illustrates an envelope 372 of the optical beating signal 371. The graph 380 illustrates an RF mode 381 of the open-ended, λ/2 RF resonator 310, in which the RF mode 381 is maximum at the ends of the RF resonator 310, and minimum (zero) at a mid-point of the RF resonator 310. It is to be noted that the envelope 372 of the optical beating signal 371 has a shape that corresponds to the RF mode 381, which is what is desired for good phase matching. The graph 390 illustrates a resulting mode overlap of the RF and optical modes as a function of longitudinal position x along the length L of the EO transducer 300.

While the graphs of FIG. 3E illustrate an ideal case in which the microwave and optical resonators are of equal length and provide perfect phase matching between the microwave and optical resonant signals (resulting in an ideal FSR-type transducer), in a practical situation, the RF and optical indices can be mismatched, which results in a mismatch between the resonance frequency ω_{RF} of the RF resonator 310 and the FSR of the optical resonator 320. For example, n_{g,opt}≈2 for many photonic materials of interest, whereas n_{RF} is often greater than 3, or even more for materials with very large permittivities, as expected for SrTiO₃ for example. In this regard, in some embodiments, phase matching can be achieved by designing the triply resonant EO transducer to have a small difference in length between the microwave resonator and the optical resonator.

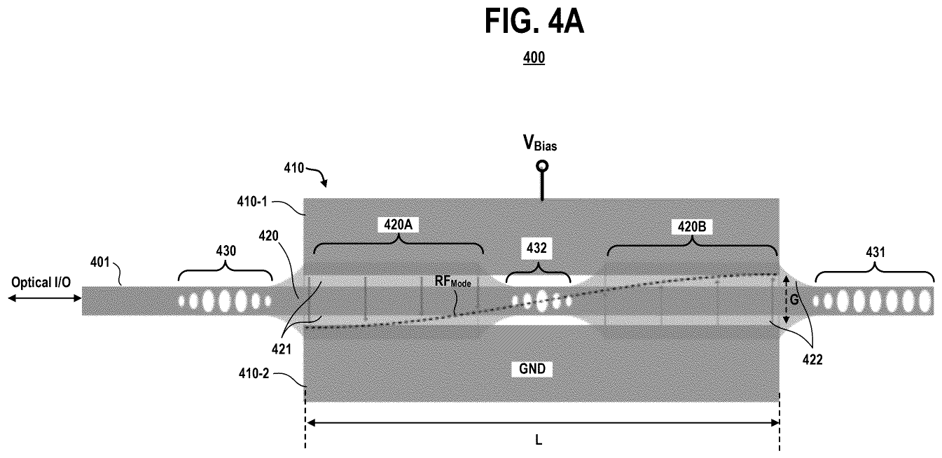

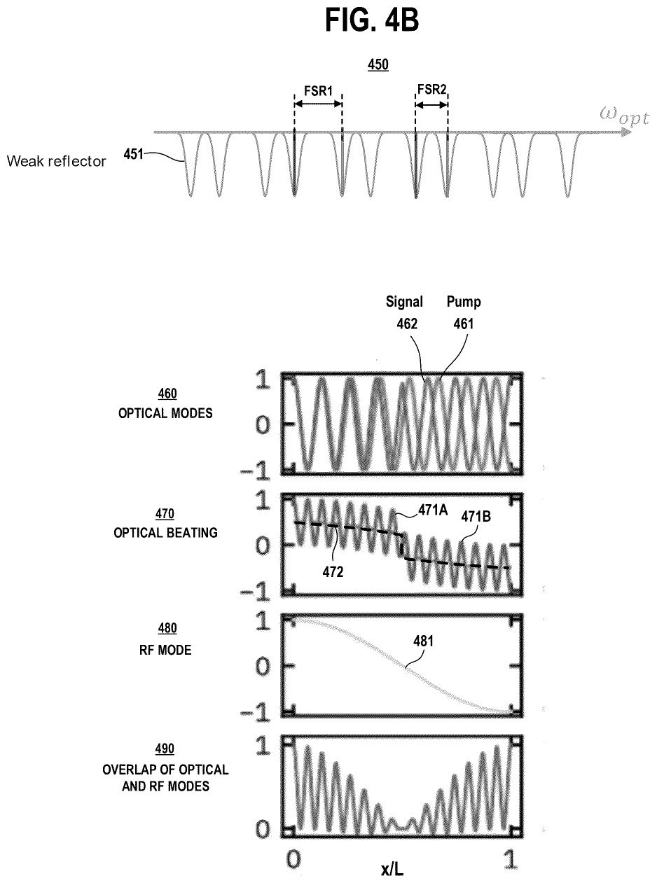

In other embodiments, phase matching is achieved for a triply resonant EO transducer by constructing the optical resonator to include a variable reflective mirror element in a mid-region of the optical resonator to engineer local phase matching in the spectrum. For example, FIG. 4A schematically illustrates an EO transducer device, according to another exemplary embodiment of the disclosure. In particular, FIG. 4A is a schematic top plan view of an EO transducer 400 which comprises an RF resonator 410 and an optical resonator 420. The RF resonator 410 comprises a first electrode pad 410-1 and a second electrode pad 410-2. The first and second electrode pads 410-1 and 410-2 are metallic electrodes with length L, and are disposed in a co-planar configuration (disposed on same X/Y plane) separated by an electrode gap G (or spacing). The ends of the first and second electrode pads 410-1 and 410-2 are open-ended (not shorted), to implement a λ/2 resonator in which the length L of the RF resonator 410 is designed to be λ/2 of a target RF signal having a fundamental operating frequency ω_{RF} (L=0.5λ_{RF}). In this regard, FIG. 4A schematically illustrates an exemplary voltage-wave distribution (denoted RF_{Mode}) of an RF signal (fundamental frequency ω_{RF}) along the length of the RF resonator 410 (open-ended, λ/2 resonator), in which the RF signal is maximum at the ends of the RF resonator 410, and minimum (zero) at a mid-point of the RF resonator 410.

The optical resonator 420 comprises a portion of an optical transmission line 401 (or optical waveguide), which is disposed in the gap G region between the first and second electrode pads 410-1 and 410-2 of the RF resonator 410. As further shown in FIG. 4A, the optical transmission line 401 comprises a first photonic crystal mirror 430 and a second photonic crystal mirror 431 disposed at end portions of the optical resonator 420, which are configured to generate optical standing-wave resonances of two optical signals along the optical resonator 420. The first photonic crystal mirror 430 comprises a partially reflective mirror, and the second photonic crystal mirror 431 comprises a fully reflective mirror. In some embodiments, the first and second photonic crystal mirrors 430 and 431 comprises integrated Bragg reflectors that are constructed with elliptical holes that are etched in the optical transmission line 401 at the ends of the optical resonator 420.

In this regard, the exemplary EO transducer 400 is similar in structure to the exemplary EO transducer 300 as discussed above. However, to compensate for moderate-to-strong mismatch between the microwave and optical indices, the EO transducer 400 implements a third photonic crystal mirror 432 (e.g., partially reflective mirror) in a middle region of the optical resonator 420, where the electric field amplitude (along the RF resonator 410) is zero (0) or near zero. In instances where the RF index is greater than the optical group index, the third photonic crystal mirror 432 in the central region of the optical resonator 420 can be designed to introduce an optical phase shift φ_{Opt} to compensate for the intrinsic wavelength mismatch where λ_{beat}≠λ_{RF} and achieve frequency matching. The third photonic crystal mirror 432 is configured to split the optical spectrum into alternating local “fast” and “slow” optical resonance pairs, where one or both of the optical resonance pairs can be matched to the microwave phase velocity. The reflectivity of the third photonic crystal mirror 432 can be finely tuned by engineering the third photonic crystal mirror 432 to have a reflectively in a range of greater than zero (0) to close to one (1). In some embodiments, the third photonic crystal mirror 432 comprises an integrated Bragg reflector which is constructed with elliptical holes that are etched in the middle region of the optical resonator 420.

The reflection properties of the third photonic crystal mirror 432 can be finely tuned based on, e.g., the number, period, size, and/or shape of the holes. In other embodiments, crenulations and other mirror structures may be used to create the index contrast, as discussed in further detail below. By increasing the reflection coefficient of the third photonic crystal mirror 432, the optical resonator 420 is essentially separated into two optical resonators, referred to herein as a first optical resonator portion 420A and a second optical resonator portion 420B, which interact by residual transmission through the third photonic crystal mirror 432, essentially forming a linear photonic molecule, similar to a ring/racetrack-photonic molecule as discussed above. In this regard, the EO transducer 400 of FIG. 4A can be considered as a hybrid of an FSR-type transducer and a photonic molecule-type ring/racetrack transducer that is implemented in a one-dimensional linear, standing wave resonator configuration.

Moreover, as schematically illustrated in FIG. 4A, the optical resonator 420 comprises a ridge waveguide structure which comprises lateral extensions 421 that are configured to enable contact between the first optical resonator portion 420A and the first and second electrode pads 410-1 and 410-2 of the RF resonator 410, and lateral extensions 422 that are configured to enable contact between the second optical resonator portion 420B and the first and second electrode pads 410-1 and 410-2 of the RF resonator 410). Again, such contact allows a DC bias voltage (denoted V_{Bias}) to be applied to one electrode (e.g., the first electrode 410-1) with the other electrode (e.g., second electrode 410-2) DC grounded. The DC bias voltage V_{Bias} is utilized in some embodiments in which the electro-optic material needs a DC bias voltage to achieve an electro-optic effect. With the exemplary voltage distribution of the RF_{Mode} as shown in FIG. 4A, a galvanic connection to apply the DC bias voltage V_{Bias} is preferably made to a central point of the EO transducer 400 where the electric field amplitude (along the RF resonator 410) is zero (0) or near zero.

FIG. 4B graphically illustrates exemplary modes of the EO transducer 400 of FIG. 4A. For example, FIG. 4B depicts a graph 450 which illustrates an optical transmission spectrum 451 of a linear triply resonator EO transducer having an architectural configuration based on the exemplary EO transducer 400 of FIG. 4A, with multiple optical resonant standing-wave modes corresponding to multiple resonance dips in the optical transmission spectrum 451. In contrast to the transmission/reflection spectrum 351 (FIG. 3E) which shows an equal FSR between each successive resonant peak, as a result of the reflection coefficient of the third photonic crystal mirror 432 (central partially reflective mirror element), the transmission/reflection spectrum 451 has a first FSR (denoted FSR1) and a second FSR (denoted FSR2) in an alternating fashion, which are unequal between each successive resonant dip or minimum (e.g., FSR1>FSR2).

As compared to the transmission/reflection spectrum 351 shown in FIG. 3E, the transmission/reflection spectrum 451 shown in FIG. 4B comprises two different FSRs (e.g., FSR1 and FSR2) allowing a choice between two different RF resonant frequencies—a first RF frequency ω_{RF1} (corresponding to FSR1) and a second RF frequency ω_{RF}2 (corresponding to FSR2), wherein ω_{RF1} is greater than ω_{RF2}. With this configuration, a broad range of frequency matching at maximum electrode coverage can be achieved through engineering the third photonic crystal mirror 432 to tune the reflection coefficient of the third photonic crystal mirror 432, to achieve triply resonant transduction. For example, the third photonic crystal mirror 432 can be designed to have (i) a relatively weak reflection coefficient in which FSR1>FSR2, or (ii) a relatively large reflection coefficient in which FSR1>>FSR2, where the EO transducer 400 behaves similarly to a typical photonic molecule comprising optical ring resonators (photonic molecule limit).

In some embodiments, the third photonic crystal mirror 432 is designed to have a center frequency which is above the optical operation frequency, and the transition between optical resonator waveguide and the third photonic crystal mirror 432 is realized with an adiabatic taper of small to larger elliptical holes. In some embodiments, it is desirable to keep an “air-mode” frequency of the mirror roughly constant far above the target frequency, and by increasing the hole size along the taper, the dielectric-mode is brought closer and closer to the target frequency. This minimizes mode-mixing and scattering losses, as the mode closest to the signal is always “dielectric-like.”

FIG. 4B further depicts various graphs 460, 470, 480, and 490, which graphically illustrate modes of a linear triply resonator EO transducer having an architectural configuration based on the exemplary EO transducer 400 of FIG. 4A. In particular, the graph 460 illustrates normalized amplitudes of two optical signal modes including an optical pump signal 461 (ω_{Pump}) and an optical signal 462 (ω_{Opt}). The graph 470 illustrates an optical beating signal comprising a first portion 471A and a second portion 471B, which results from the combination of the optical resonant standing waves of the optical pump signal 461 and the optical signal 462, as a function of longitudinal position x along the length L of the EO transducer 400. In addition, the graph 470 illustrates an envelope 472 of the first and second portions 471A and 471B of the optical beating signal. The graph 480 illustrates an RF mode 481 of the open-ended, λ/2 RF resonator 410, in which the RF signal is maximum at the ends of the RF resonator 410, and minimum (zero) at a mid-point of the RF resonator 410. The graph 490 illustrates a resulting mode overlap of the RF and optical modes as a function of longitudinal position x along the length L of the EO transducer 400.

In this regard, the graphs 470 and 480 illustrate that an implementation of the third photonic crystal mirror 432 introduces an optical phase shift φ_{Opt} to compensate for an intrinsic wavelength mismatch where λ_{beat}≠λ_{RF}, where λ_{beat} is the wavelength of the envelope of the optical beating and λ_{RF} is the wavelength of the RF signal. For example, the graph 480 of the RF mode 481 shows that for the RF resonator 410 having a physical length of L=0.5 λ_{RF} and no RF phase shift (φ_{RF}=0), matching can be achieved by configuring the third (partially reflective) photonic crystal mirror 432 to provide an optical phase shift (e.g., φ_{Opt}=0.3π) to achieve an effective optical resonator length (e.g., L=0.35 λ_{beat}) which is less than L=0.5 λ_{beat}, and thereby achieve an intrinsic match between λ_{RF} and λ_{beat}.

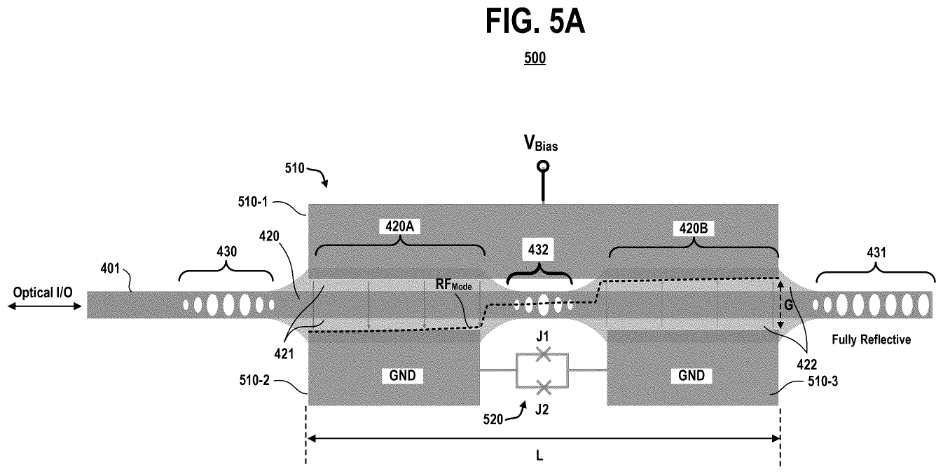

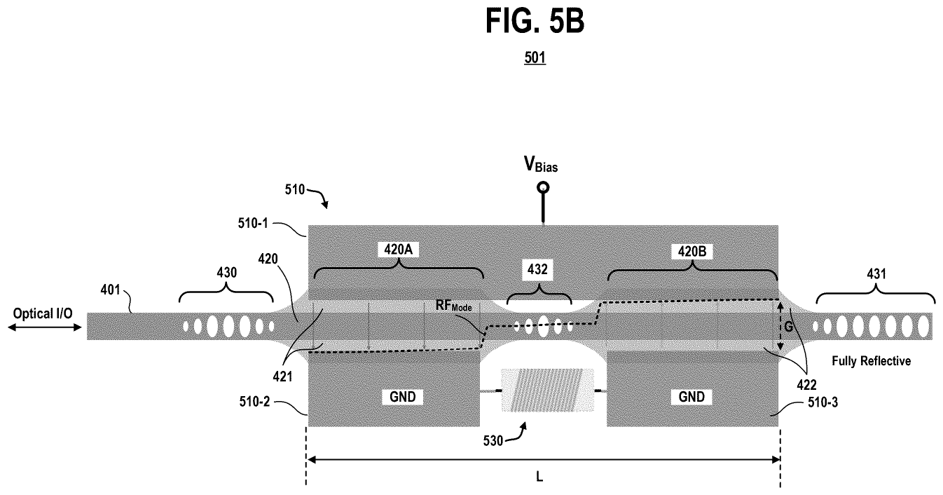

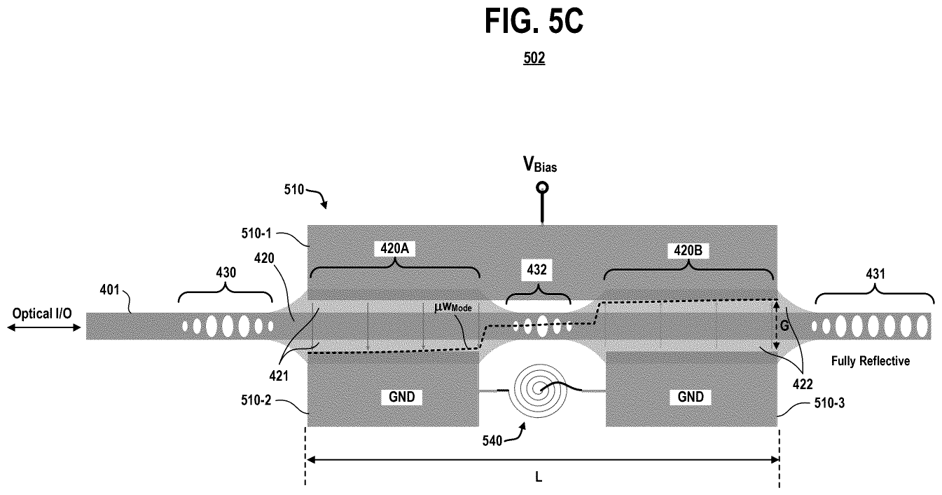

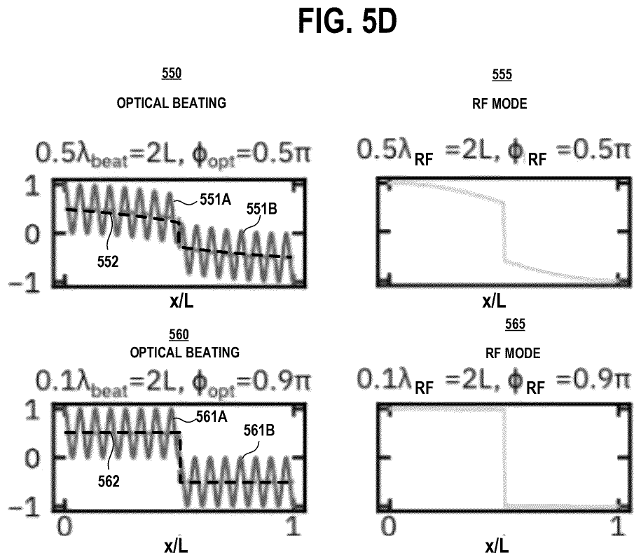

FIG. 5A schematically illustrates an EO transducer device, according to another exemplary embodiment of the disclosure. In particular, FIG. 5A is a schematic top plan view of an EO transducer 500 which comprises a structural configuration which is similar to that of the EO transducer 400 of FIG. 4A, except that the EO transducer 500 comprises an RF resonator 510 which comprises a first electrode pad 510-1, a second electrode pad 510-2, a third electrode pad 510-3, and a superconducting quantum interference device (SQUID) 520 coupled between the second and third electrode pads 510-2 and 510-3. The SQUID 520 comprises a superconducting loop formed by a parallel connection of first and second Josephson junctions J1 and J2. The second electrode pad 510-2 is coupled to the lateral extension 421 of the first optical resonator portion 420A, and the third electrode pad 510-3 is coupled to the lateral extension 422 of the second optical resonator portion 420B.

As schematically illustrated in FIG. 5A, the lateral gap (electrode pad discontinuity) between the second and third electrode pads 510-2 and 510-3 results in an exemplary voltage-wave distribution (denoted RF_{Mode}) of an RF signal (fundamental frequency ω_{RF}) along the length of the RF resonator 510, in which the RF signal is maximum at the ends of the RF resonator 510, and essentially a minimum (zero) along the length of the lateral gap (electrode pad discontinuity) between the second and third electrode pads 510-2 and 510-3. In the exemplary configuration of FIG. 5A, the SQUID 520 is an inductor element that essentially introduces a strong inductance between the second and third electrode pads 510-2 and 510-3, which reduces an effective microwave length of the RF resonator 510. As a result, the physical length L of the EO transducer 500 can be reduced relative to the physical lengths L of the EO transducers 300 and 400 as discussed above, where L=0.5 λ_{RF} for a target RF signal having a fundamental operating frequency ω_{RF}. For example, in FIG. 5A, the EO transducer 500 can be designed to have a length L<0.5 λ_{RF} (e.g., L=0.25 λ_{RF}, 0.10 λ_{RF}, etc.). The inductance of the SQUID 520 can be tuned by applying a flux bias through the superconducting loop of the SQUID 520 using known techniques. For example, the magnetic flux applied to the SQUID 520 (for tuning the inductance of the RF resonator 510) comprises an external magnetic field that is generated off-chip by a magnetic coil structure. In other embodiments, the magnetic flux applied to the superconducting loop of the SQUID 520 is generated on-chip using suitable techniques, e.g., applying DC tuning current to a flux line or inductor that is disposed adjacent to the superconducting loop of the SQUID 520 to generate a magnetic flux or mutual inductance that is passed through the superconducting loop of the SQUID 520 to tune the inductance of the SQUID 520.

The introduction of an inductor element (e.g., the SQUID 520) at the central region of the RF resonator 510 essentially serves to introduce an RF phase shift PRF to achieve the desired T-shift over the length L of the RF resonator 510, where L is much shorter than ½ the microwave wavelength (e.g., L<<0.5 λ_{RF}), which allows a reduction in the footprint (e.g., length L) of the EO transducer 500. Indeed, in instances where the inductor element provides relatively strong inductive coupling in the central region of the RF resonator 510, the effective RF wavelength can be significantly reduced, thereby reducing the physical length L of the EO transducer 500 towards the photonic molecule limit (since at a fixed target RF-frequency, reducing the device length L will increase the optical FSR, and therefore represent the photonic molecule regime). The implementation of the SQUID 520 as an inductor element is particularly useful for triply resonant EO transducers that are configured to operate in cryogenic environments.

FIG. 5B schematically illustrates an EO transducer device, according to another exemplary embodiment of the disclosure. In particular, FIG. 5B is a schematic top plan view of an EO transducer 501 which comprises a structural configuration which is similar to that of the EO transducer 500 of FIG. 5A, except that the RF resonator 510 implements a surface mount device (SMD) coil 530 that is coupled to and between the second and third electrode pads 510-2 and 510-3 to provide an inductive element instead of the SQUID 520 in FIG. 5A. In this configuration, the EO transducer 501 can be operated in a room temperature environment, while achieving RF resonator quality factors greater than 10, even at room temperature.

FIG. 5C schematically illustrates an EO transducer device, according to another exemplary embodiment of the disclosure. In particular, FIG. 5C is a schematic top plan view of an EO transducer 502 which comprises a structural configuration which is similar to that of the EO transducers 500 and 501 of FIGS. 5A and 5B, except that the RF resonator 510 implements an integrated (on-chip) spiral inductor 540 that is coupled to and between the second and third electrode pads 510-2 and 510-3 to provide an inductive element The connection between the integrated (on-chip) spiral inductor 540 and, e.g., the third electrode pad 510-3 can be implemented using vertical vias or airbridges. It is to be noted that FIG. 5C merely illustrates an exemplary non-limiting embodiment for implementing an inductive element using a spiral inductor geometry, and that other geometric inductor patterns can be implemented, which are suitable for the given application. For operation in a cryogenic environment, the integrated (on-chip) spiral inductor 540 can be formed of a superconductor such as niobium, niobium nitride, etc.

FIG. 5D depicts various graphs 550, 555, 560 and 565, which graphically illustrate modes of a linear triply resonant EO transducer having an architectural configuration based on the exemplary EO transducers 500, 501, and 502 of FIGS. 5A, 5B, and 5C, wherein the RF resonator 510 comprises an inductive element to reduce the footprint (e.g., length L) of the EO transducer device. For example, the graph 550 illustrates an optical beating signal comprising a first portion 551A and a second portion 551B, which results from the combination of optical resonant standing waves of an optical pump signal and an optical signal, as a function of longitudinal position x along the length L of the EO transducer. In addition, the graph 550 illustrates an envelope 552 of the first and second portions 551A and 551B of the optical beating signal. The graph 555 illustrates an RF mode of the RF resonator 510, in which the RF signal is maximum at the ends of the RF resonator 510, and has a sharp transition at a mid-point of the RF resonator 510. The graphs 550 and 555 illustrate signal modes for an EO transducer having a length L=0.25 λ_{RF}, wherein the implementation of an inductive element at a center region of the RF resonator 510 provides an RF phase shift φ_{RF}=0.5π, and wherein the third (partially reflective) photonic crystal mirror 432 is designed to provide an optical phase shift φ_{Opt}=0.5π to ensure a match between λ_{RF} and λ_{beat}.

Similarly, the graph 560 illustrates an optical beating signal comprising a first portion 561A and a second portion 561B, which results from the combination of optical resonant standing waves of an optical pump signal and an optical signal, as a function of longitudinal position x along the length L of the EO transducer. In addition, the graph 560 illustrates an envelope 562 of the first and second portions 561A and 561B of the optical beating signal. The graph 565 illustrates an RF mode of the RF resonator 510, in which the RF signal is maximum at the ends of the RF resonator 510, and has a sharp transition at a mid-point of the RF resonator 510. The graphs 560 and 565 illustrate signal modes for an EO transducer having a length L=0.10 λ_{RF}, wherein the implementation of an inductive element at a center region of the RF resonator 510 provides an RF phase shift φ_{RF}=0.9π, and wherein the third (partially reflective) photonic crystal mirror 432 is designed to provide an optical phase shift φ_{Opt}=0.9 to ensure a match between λ_{RF} and λ_{beat}. The graphs 560 and 565 illustrate a linear, triply resonant EO transducer in the photonic molecule limit, wherein the length L of the EO transducer is much shorter than the RF wavelength, due to a strong inductance of an inductive element.

Again, it is to be noted that the triply resonant EO transducers shown in FIGS. 4A, 5A, 5B, and 5C illustrate exemplary embodiments in which the optical resonator 420 effectively comprises two separate optical resonators (e.g., the first optical resonator portion 420A and the second optical resonator portion 420B) which are optically coupled through the third (partially reflective) photonic crystal mirror 432. The strength of the optical coupling between the first optical resonator portion 420A and the second optical resonator portion 420B depends on the reflection properties of the third (partially reflective) photonic crystal mirror 432.

For example, on one hand, the optical beating signal portions 471A and 471B shown in graph 470 of FIG. 4B illustrates an exemplary embodiment in which the reflection coefficient of the third (partially reflective) photonic crystal mirror 432 is relatively small to provide strong optical coupling between the first optical resonator portion 420A and the second optical resonator portion 420B of the optical resonator 420, which results in a relatively small optical phase shift φ_{Opt} (e.g., φ_{=Opt}=0.3π). On the other hand, the optical beating signal portions 561A and 561B shown in graph 560 of FIG. 5D illustrates an exemplary embodiment in which the reflection coefficient of the third (partially reflective) photonic crystal mirror 432 is relatively large to provide weak optical coupling between the first optical resonator portion 420A and the second optical resonator portion 420B of the optical resonator 420, which results in a relatively large optical phase shift φ_{Opt} (e.g., φ_{Opt}=0.9π). Moreover, the optical beating signal portions 551A and 551B shown in graph 550 of FIG. 5D illustrates an exemplary embodiment in which the reflection coefficient of the third (partially reflective) photonic crystal mirror 432 is at some value between the small and large reflection coefficient values, to provide medium optical coupling between the first optical resonator portion 420A and the second optical resonator portion 420B of the optical resonator 420, which results in a mid-level optical phase shift φ_{Opt} (e.g., φ_{Opt}=0.5π).

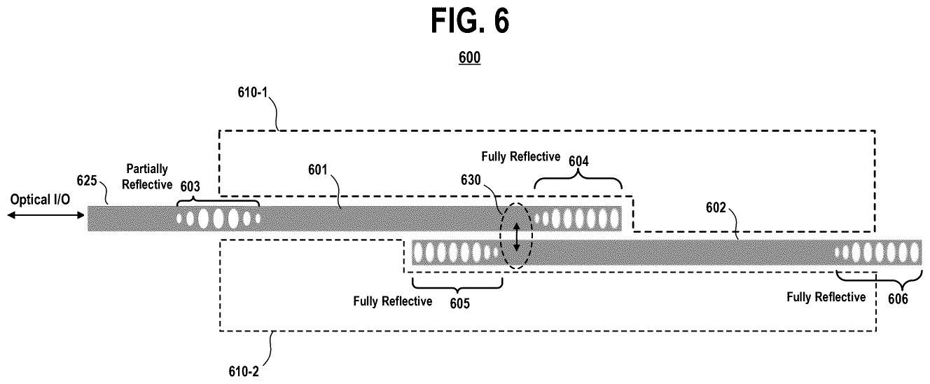

It is to be noted that FIGS. 3A-3C, 3D, 4A, and 5A-5C illustrate exemplary embodiments of linear triply resonant EO transducers which include optical resonators that are comprised of a single optical transmission line disposed in a gap region between electrode pads of an RF resonator. In other embodiments, as schematically shown in FIG. 6, the optical resonator of a linear, triply resonant EO transducer device, can be designed to have two optical transmission lines disposed between a gap region between electrode pads of an RF resonator.

In particular, FIG. 6 schematically illustrates an optical resonator 600 which comprises a first optical resonator portion 601 and a second optical resonator portion 602, which are configured for evanescent directional optical coupling to each other. The first optical resonator portion 601 is formed at an end portion of an optical bus waveguide 625 in which optical I/O signals are transmitted. The first optical resonator portion 601 comprises an optical transmission line that is disposed between a first photonic crystal mirror 603 and a second photonic crystal mirror 604, wherein the first photonic crystal mirror 603 comprises a partially reflective mirror, and the second photonic crystal mirror 604 comprises a fully reflective mirror. The second optical resonator portion 602 comprises an optical transmission line that is disposed between a third photonic crystal mirror 605 and a fourth photonic crystal mirror 606, wherein the third and fourth photonic crystal mirrors 605 and 606 each comprises a fully reflective mirror. An end portion of the first optical resonator portion 601 overlaps an end portion of the second optical resonator portion 602 to enable evanescent directional coupling of the optical modes between the first and second optical resonator portions 601 and 602. In the exemplary configuration shown in FIG. 6, optical signals (optical pump signal and optical signals) are input/output to/from the optical resonator 600 through the partially reflective first photonic crystal mirror 603.

FIG. 6 further depicts dashed-line outline boxes which schematically represent an exemplary layout and placement of a first electrode pad 610-1 and a second electrode pad 610-2 of an RF resonator. As with the exemplary embodiments of the EO transducers as discussed above, the first and second optical resonator portions 601 and 602 are disposed in a gap region between the first and second electrode pads 610-1 and 610-2. In addition, while not specifically shown in FIG. 6, the first and second optical resonator portions 601 and 602 can be constructed as ridge optical waveguide structures to enable direct contact between the first and second electrode pads 610-1 and 610-2 and the first and second optical resonator portions 601 and 602 or rib waveguide structures.

It is to be noted that the exemplary configuration of the optical resonator 600 shown in FIG. 6 can be considered to be functionally/operationally equivalent to the optical resonator 420 of FIG. 4A, wherein the partially reflective third photonic crystal mirror 432 between the first optical resonator portion 420A and the second optical resonator portion 420B (FIG. 4A) is essentially replaced by the fully reflective second and third photonic crystal mirrors 604 and 605 with an overlapping region 630 between the ends of the first and second optical resonator portions 601 and 602 serving as a directional coupler to enable coupling of optical resonant signals between the overlapping ends of the first and second optical resonator portions 601 and 602. In an exemplary embodiment, the overlapping region 630 is disposed in a central region of the optical resonator 600 where the amplitudes of the microwave and optical beating signal modes are zero (0) or close to zero.

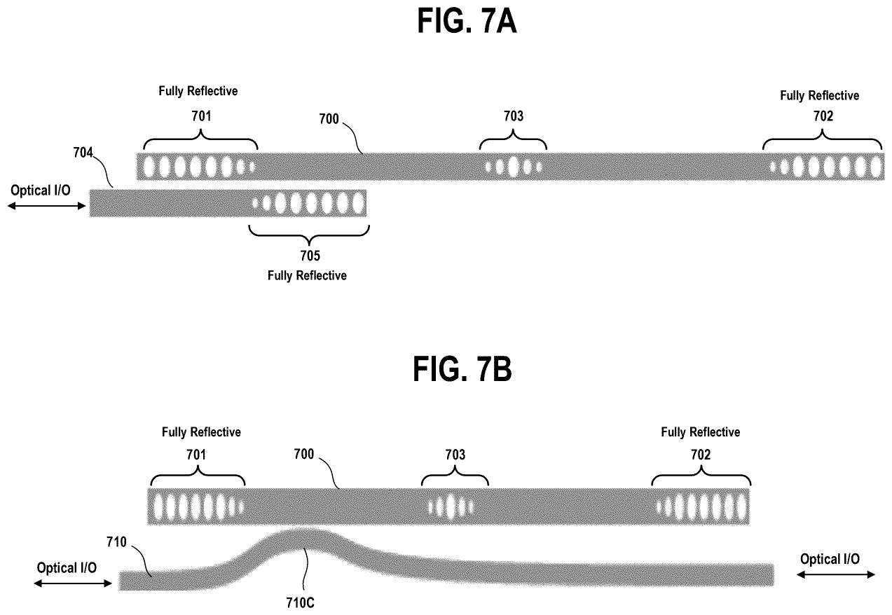

In other embodiments, the coupling of optical I/O signals to and from an optical resonator of a linear, triply resonant EO transducer can be implemented using a directional coupler. For example, FIG. 7A schematically illustrates a method for coupling optical signals to and from an optical resonator of an EO transducer device using an optical directional coupler, according to an exemplary embodiment of the disclosure. In particular, FIG. 7A schematically illustrates an optical transmission line which comprises an optical resonator 700 disposed between a first photonic crystal mirror 701 and a second photonic crystal mirror 702, wherein the first and second photonic crystal mirrors 701 and 702 each comprise a fully reflective mirror. The optical resonator 700 further comprises a third photonic crystal mirror 703 disposed in a mid-region of the optical resonator 700. Similar to the exemplary embodiments discussed above, the third photonic crystal mirror 703 comprises a partially reflective mirror that is engineered as a matching mirror element to introduce an optical phase shift φ_{Opt} in the optical resonant modes of the optical resonator 700 to compensate for an intrinsic wavelength mismatch between λ_{beat} and λ_{RF}.

In addition, FIG. 7A schematically illustrates an optical transmission line 704 (e.g., optical bus waveguide) which comprises a photonic crystal mirror 705 disposed at an end portion thereof, wherein the photonic crystal mirror 705 comprises a fully reflective mirror. The end portion of the optical transmission line 704 overlaps an end portion of the optical resonator 700 to provide an optical directional coupler region that enables evanescent directional coupling of optical I/O signals between the optical transmission line 704 and the optical resonator 700. It is to be noted that the combination of the two fully reflective first and second photonic crystal mirrors 701 and 705 and the overlapping portions of the optical resonator 700 and the optical transmission line 704 can be can be considered as functionally/operationally equivalent to, e.g., the partially reflective first photonic crystal mirror 430 of the optical transmission line 401 of FIG. 4A, wherein the partially reflective first photonic crystal mirror 430 enables the optical coupling of optical I/O signals in and out of the optical resonator 420.

Next, FIG. 7B schematically illustrates a method for coupling optical signals to and from an optical resonator of an EO transducer device using an optical directional coupler, according to another exemplary embodiment of the disclosure. In particular, FIG. 7B schematically illustrates an optical transmission line which comprises the optical resonator 700 and first, second, and third photonic crystal mirrors 701, 702, and 703 as described above in conjunction with FIG. 7A. In addition, FIG. 7B schematically illustrates an optical transmission line 710 which comprises a directional coupler portion 710C that is configured to adiabatically/evanescently couple optical I/O signals to and from the optical resonator 700. In the exemplary configuration shown in FIG. 7B, optical I/O signals (optical pump signal and optical signals) can be input/output to/from one or both ends of the optical transmission line 710, depending on the application.

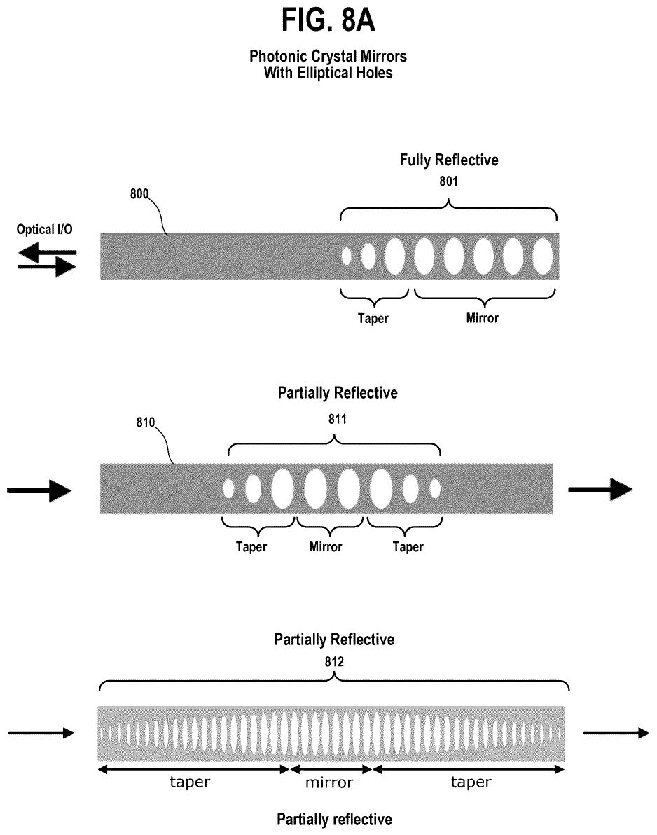

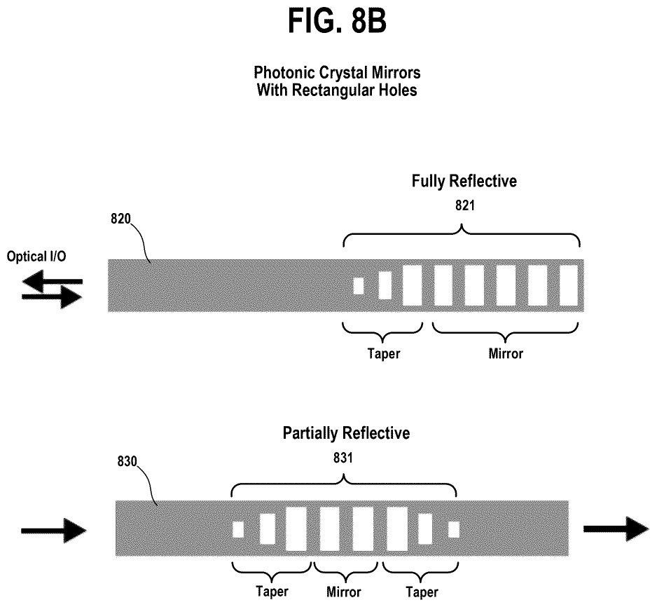

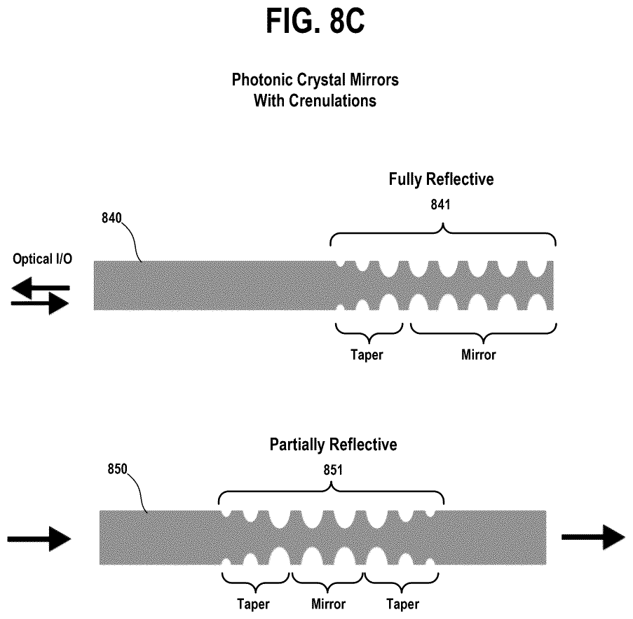

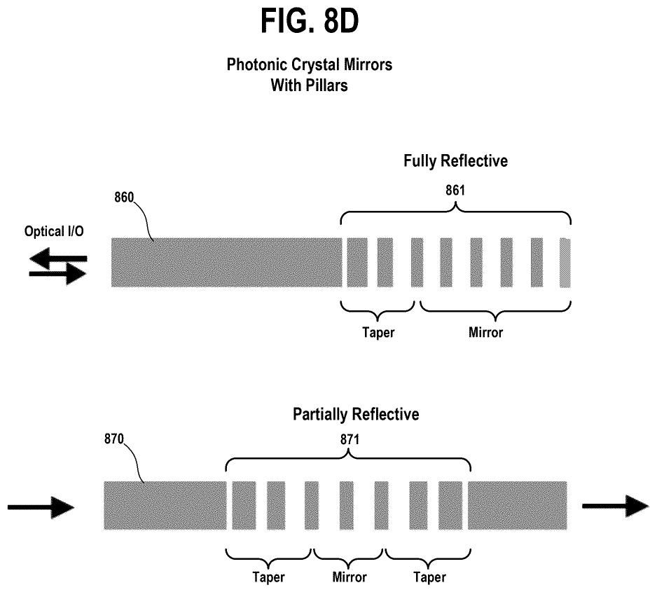

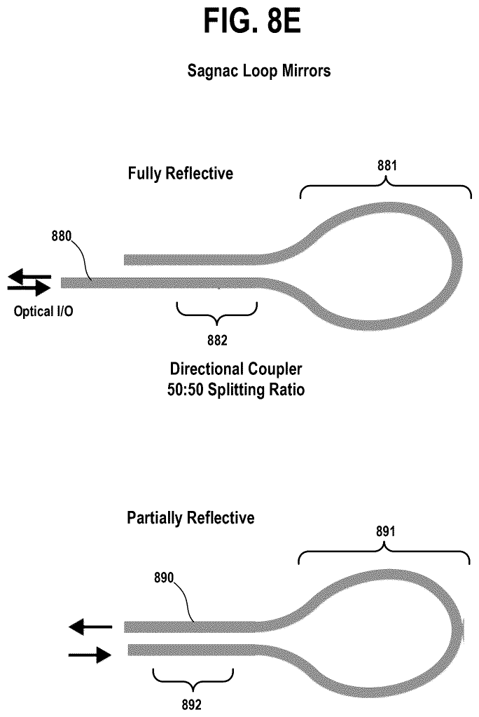

Next, FIGS. 8A, 8B, 8C, and 8D schematically illustrate various types of photonic crystal mirrors that can be used to implement triply resonant EO transducers. In particular, FIG. 8A schematically illustrates photonic crystal mirrors with elliptical holes, which can be used to implement triply resonant EO transducers according to exemplary embodiments of the disclosure. For example, FIG. 8A schematically illustrates an optical transmission line 800 with a fully reflective photonic crystal mirror 801 (e.g., Bragg reflector) that is formed by etching a pattern of elliptical holes in an end portion of the optical transmission line 800 to form a fully reflective mirror. The fully reflective photonic crystal mirror 801 comprises a tapered section and a mirror section. In addition, FIG. 8A schematically illustrates an optical transmission line 810 with a partially reflective photonic crystal mirror 811 (e.g., Bragg reflector) that is formed by etching elliptical holes in the optical transmission line 810 to form a partially reflective mirror. The partially reflective photonic crystal mirror 811 comprises a mirror section disposed between tapered sections. Similarly, FIG. 8A schematically illustrates a partially reflective photonic crystal mirror 812 (e.g., Bragg reflector) that is formed by etching a pattern of elliptical holes in an optical transmission line to form a partially reflective mirror. The partially reflective photonic crystal mirror 812 comprises a mirror section disposed between tapered sections. The reflection coefficient of the partially reflective photonic crystal mirrors 811 and 812 can be engineered by, e.g., the number and size of the elliptical holes, etc.

Next, FIG. 8B schematically illustrates an optical transmission line 820 with a fully reflective photonic crystal mirror 821 that is formed by etching a pattern of rectangular holes in an end portion of the optical transmission line 820 to form a fully reflective mirror. The fully reflective photonic crystal mirror 821 comprises a tapered section and a mirror section. In addition, FIG. 8B schematically illustrates an optical transmission line 830 with a partially reflective photonic crystal mirror 831 that is formed by etching a pattern of rectangular holes in an optical transmission line 810 to form a partially reflective mirror. The partially reflective photonic crystal mirror 831 comprises a mirror section disposed between tapered sections. The reflection coefficient of the partially reflective photonic crystal mirror 831 can be engineered by, e.g., the number and size of the rectangular holes, etc.

Next, FIG. 8C schematically illustrates photonic crystal mirrors with crenulations, which can be used to implement triply resonant EO transducers according to exemplary embodiments of the disclosure. For example, FIG. 8C schematically illustrates an optical transmission line 840 with a fully reflective photonic crystal mirror 841 that is formed by etching a pattern of crenulations in an end portion of the optical transmission line 840 to form a fully reflective mirror. The fully reflective photonic crystal mirror 841 comprises a tapered section (where the crenulations increase in size) and a mirror section (where the crenulations are the same size). In addition, FIG. 8C schematically illustrates an optical transmission line 850 with a partially reflective photonic crystal mirror 851 that is formed by etching a pattern of crenulations in a portion of the optical transmission line 850 to form a partially reflective mirror. The partially reflective photonic crystal mirror 851 comprises a mirror section disposed between tapered sections. The reflection coefficient of the partially reflective photonic crystal mirror 851 can be engineered by, e.g., the number and size of the crenulations holes, etc.

Next, FIG. 8D schematically illustrates photonic crystal mirrors with pillar structures, which can be used to implement triply resonant EO transducers according to exemplary embodiments of the disclosure. For example, FIG. 8D schematically illustrates an optical transmission line 860 with a fully reflective photonic crystal mirror 861 that is formed by etching a pattern of pillars in an end portion of the optical transmission line 860 to form a fully reflective mirror. The fully reflective photonic crystal mirror 861 comprises a tapered section (where the sizes (widths) of the pillars decrease and the spacings between the pillars increase) and a mirror section (where the pillars are the same size and separated by a same spacing). In addition, FIG. 8D schematically illustrates an optical transmission line 870 with a partially reflective photonic crystal mirror 871 that is formed by etching pillar structures in a portion of the optical transmission line 870 to form a partially reflective mirror. The partially reflective photonic crystal mirror 871 comprises a mirror section disposed between tapered sections. The reflection coefficient of the partially reflective photonic crystal mirror 871 can be engineered by, e.g., the number and size of the pillar structures and the spacing between the pillar structures, etc.

FIG. 8E schematically illustrates Sagnac loop mirrors, which can be used to implement triply resonant EO transducers according to exemplary embodiments of the disclosure. For example, FIG. 8E schematically illustrates an optical transmission line which comprises a fully reflective Sagnac loop mirror 880 having a loop section 881 (with an open-end portion) and a directional coupler section 882. The directional coupler section 882 is engineered to provide a 50:50 splitting ratio to form a fully reflective mirror where the optical signals are input/output to/from one end of the Sagnac loop mirror 880. In addition, FIG. 8E schematically illustrates an optical transmission line which comprises a partially reflective Sagnac loop mirror 890 having a loop section 891 and a coupler section 892. The coupler section 892 is engineered to provide a given splitting ratio to form a partially reflective mirror wherein the optical signals are input/output to/from both ends of the partially reflective Sagnac loop mirror 890.

Next, FIGS. 9A-9D schematically illustrate various techniques for coupling RF I/O signals to/from a triply resonant EO transducer. For example, FIG. 9A schematically illustrates a method for capacitively coupling RF I/O signals to/from a triply resonant EO transducer according to an exemplary embodiment of the disclosure. In particular, FIG. 9A schematically illustrates a coupling structure 900 that is configured to capacitively couple RF I/O signals to and from the exemplary EO transducer 400 of FIG. 4A. The coupling structure 900 comprises a coplanar waveguide comprising ground conductors 901 and 902 and a signal line 903 disposed between the ground conductors 901 and 902. The signal line 903 is connected to a coupling pad 904 (or capacitor pad) which is disposed adjacent, and in close proximity, to an edge of the first electrode pad 410-1 of the RF resonator 410, to thereby enable capacitive coupling of RF I/O signals between the signal line 903 and the first electrode pad 410-1 of the RF resonator 410. In some embodiments, such as shown in FIG. 9A, the coupling pad 904 is disposed in alignment to an end of the first electrode pad 410-1 of the RF resonator 410 where the RF mode is maximum, to provide maximum coupling strength.

Next, FIG. 9B schematically illustrates a method for capacitively coupling RF I/O signals to/from a triply resonant EO transducer according to another exemplary embodiment of the disclosure. In particular, FIG. 9B schematically illustrates a coupling structure 910 that is configured for capacitively coupling RF I/O signals to and from the exemplary EO transducer 400 of FIG. 4A. The coupling structure 910 is similar to the coupling structure of FIG. 9A, except that the signal line 903 is connected to a tuning electrode 914 (or contact pad) which is disposed adjacent, and in close proximity, to an edge of the first electrode pad 410-1 of the RF resonator 410, and which makes contact to the lateral extension 422 of the second optical resonator portion 420B. In this exemplary configuration, the tuning electrode 914 and the first electrode pad 410-1, with a reduced length, collectively form an electrode pad (with length L) of the RF resonator 410. The tuning electrode 914 is configured to capacitively couple RF I/O signals between the signal line 903 and the RF resonator 410, wherein the tuning electrode 914 is disposed in alignment to an end portion of the RF resonator 410 where the RF mode is maximum, to provide maximum coupling strength.

Moreover, as further shown in FIG. 9B, a DC tuning voltage can be applied to the signal line 903 which, in turn, is applied to the lateral extension 422 of the second optical resonator portion 420B via the tuning electrode 914, to thereby enable selective tuning of the second optical resonator portion 420B of the EO transducer 400. Such selective tuning is particularly advantageous in operating regimes of the EO transducer 400 (such as discussed above in conjunction with FIG. 5D) where, for example, the EO transducer 400 is relatively small in length (e.g., L<<0.5 λ_{RF}), and the third photonic crystal mirror 432 is designed to have strong reflection properties to achieve a desired optical phase shift φ_{Opt} to compensate for the intrinsic wavelength mismatch between λ_{RF} and λ_{beat}. As noted above, in such operating regimes, the optical resonator 420 effectively comprises two separate optical resonators (e.g., the first optical resonator portion 420A and the second optical resonator portion 420B) that are weakly coupled through the third photonic crystal mirror 432. In such operating regimes, it becomes critical for the first optical resonator portion 420A and the second optical resonator portion 420B to have the same resonant frequency (or substantially identical resonant frequencies) to enable optical interaction between the first and second optical resonator portions 420A and 420B.

In the exemplary configuration shown in FIG. 9B, a DC tuning voltage can be applied to the second optical resonator portion 420B, as needed, to tune the resonant frequency of the second optical resonator portion 420B to match the resonant frequency of the first optical resonator portion 420A. While the DC bias voltage V_{Bias} is applied to both the first and second optical resonator portions 420A and 420B, the DC tuning voltage would be applied to only the second optical resonator portion 420B via the tuning electrode 914 (which is DC isolated from first electrode pads 410-1). In this instance, the first and second optical resonator portions 420A and 420B would be DC biased to enable the EO effect and drive the transduction process, but with different effective DC bias voltages to change the relative DC tuning between the first and second optical resonator portions 420A and 420B for the purposes of achieve matching resonant frequencies of the first and second optical resonator portions 420A and 420B.

Next, FIG. 9C schematically illustrates a method for galvanically coupling RF I/O signals to/from a triply resonant EO transducer according to an exemplary embodiment of the disclosure. In particular, FIG. 9C schematically illustrates a coupling structure 920 that is configured to galvanically couple RF I/O signals and apply the DC bias voltage to and from the exemplary EO transducer 400 of FIG. 4A. The coupling structure 920 is similar to the coupling structure of FIG. 9A, except that the signal line 903 is galvanically connected to the first electrode pad 410-1 of the RF resonator 410 at a given offset point from the central symmetry point of the EO transducer 400. In this configuration, the RF coupling strength can be controlled by the location of the connection point of the signal line 903 to the first electrode pad 410-1, wherein the RF coupling strength is essentially zero (0) at the central symmetry point of the EO transducer 400 (e.g., at the location of the DC bias line for V_{Bias}), and wherein the RF coupling strength increases as the galvanic connection point between the signal line 903 and the first electrode pad 410-1 is further offset from the central symmetry point of the EO transducer 400. With the galvanic RF coupling configuration of FIG. 9C, a maximum RF coupling is achieved with the signal line 903 connected to the end of the first electrode pad 410-1. As compared to capacitive RF coupling mechanisms, the galvanic RF coupling mechanism of FIG. 9C provides less disturbance of the RF mode.

It is to be noted that FIG. 9C illustrates an exemplary embodiment in which a DC bias voltage V_{Bias} is applied to the EO transducer 400 via a separate, dedicated DC bias line that is galvanically coupled to a mid-point of the RF resonator 410. However, in other embodiments, since the signal line 903 is galvanically coupled to the first electrode pad 410-1, the signal line 903 can be utilized for DC biasing the optical resonator 420, as well as for RF I/O. In such embodiments, the DC bias voltage V_{Bias} would be applied to the first electrode pad 410-1 via the signal line 903, thus eliminating the need for the dedicated DC bias line shown in FIG. 9C.

Next, FIG. 9D schematically illustrates a method for capacitively coupling RF I/O signals to/from a triply resonant EO transducer according to another exemplary embodiment of the disclosure. In particular, FIG. 9D schematically illustrates coupling structure 930 that is configured for capacitively coupling RF I/O signals to and from the exemplary EO transducer 400 of FIG. 4A. The coupling structure 930 comprises a coplanar waveguide comprising ground conductors 931 and 932, and a signal line 933 disposed between the ground conductors 931 and 932. The signal line 933 is disposed adjacent, and in close proximity, to an end of the first electrode pad 410-1 of the RF resonator 410, to enable capacitive coupling of RF I/O signals between the signal line 933 and the first electrode pad 410-1 of the RF resonator 410. The coupling structure 930 enables inline capacitive coupling at an end of the EO transducer 400 where the RF mode is maximum, to provide maximum coupling strength.

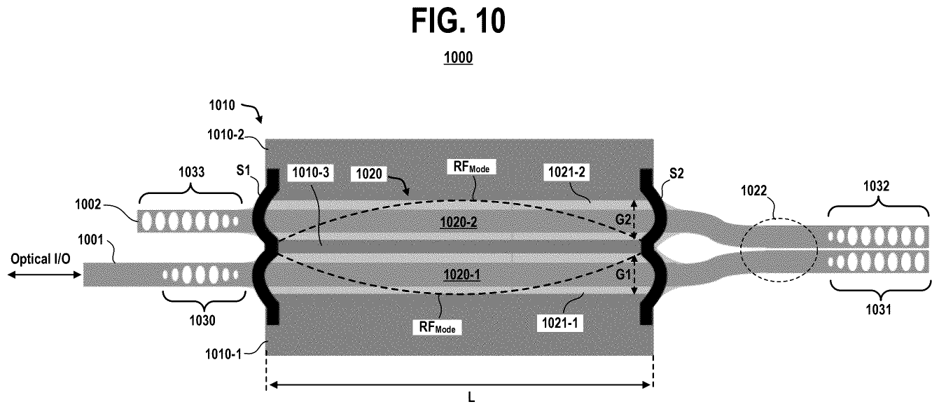

FIG. 10 schematically illustrates an EO transducer device, according to another exemplary embodiment of the disclosure. In particular, FIG. 10 schematically illustrates an EO transducer 1000 which comprises a first optical transmission line 1001 (or first optical waveguide), a second optical transmission line 1002 (or second optical waveguide), an RF resonator 1010, an optical resonator 1020, an optical directional coupler 1022, and photonic crystal mirrors 1030, 1031, 1032, and 1033. The RF resonator 1010 comprises a first electrode pad 1010-1, a second electrode pad 1010-2, and a third electrode pad 1010-3. The first, second, and third electrode pads 1010-1, 1010-2, and 1010-3 are metal/metallic electrodes with length L, and are disposed in a co-planar configuration (disposed on same X/Y plane), wherein the first and third electrode pads 1010-1 and 1010-3 are separated by a first electrode gap G1, and the second and third electrode pads 1010-2 and 1010-3 are separated by a second electrode gap G2. In some embodiments, the first and second gap G1 and G2 are equal (e.g., 0.5 micron) and designed to optimize an efficiency of the optical-RF transduction process.

The EO transducer 1000 comprises a co-planar waveguide (CPW) architecture wherein the RF resonator 1010 comprises a CPW resonator in which the third electrode pad 1010-3 (which corresponds to a CPW center conductor or signal line) is disposed between the first and second electrode pads 1010-1 and 1010-2 (which correspond to CPW ground conductors). In addition, as schematically illustrated in FIG. 10, the first, second and third electrode pads 1010-1, 1010-2, and 1010-3 have (i) first ends that are electrically shorted to each other via wiring S1, and (ii) second ends that are electrically shorted to each other via wiring S2. In this configuration, the RF resonator 1010 comprises a close-ended, half-wavelength (λ/2) resonator in which the length L of the RF resonator 1010 is designed to be λ/2 of a target RF signal having a fundamental operating frequency ω_{RF} (i.e., L=0.5 λ_{RF}). In this regard, FIG. 10 schematically illustrates exemplary voltage-wave distributions (RF_{Mode}) of an RF signal (fundamental frequency ω_{RF}) along the length of the RF resonator 1010 in which the RF signal is minimum (zero) at the ends of the RF resonator 1010, and maximum at a mid-point of the RF resonator 1010. The first, second, and third electrode pads 1010-1, 1010-2, and 1010-3 can be formed of any type of metal or metallic material which is suitable for the given application. For example, in embodiments where the EO transducer 1000 is configured to operate in a cryogenic environment, the first, second, and third electrode pads 1010-1, 1010-2, and 1010-3 can be formed of a superconducting metal/metallic material having a suitable critical temperature (Tc), such as Al, Nb, Ta, Ti, W, Sn, Mo, or nitrides of the same, or combinations thereof, and/or the like. While not specifically shown in FIG. 10, it is to be noted that RF I/O can be implemented using any suitable one of the RF coupling mechanisms discussed above in conjunction with FIGS. 9A-9D.

The optical resonator 1020 comprises a first optical resonator portion 1020-1 and a second optical resonator portion 1020-2. The first optical resonator portion 1020-1 comprises a portion of the first optical transmission line 1001 which is disposed in the first electrode gap G1 between the first and third electrode pads 1010-1 and 1010-3. The second optical resonator portion 1020-2 comprises a portion of the second optical transmission line 1002 which is disposed in the second electrode gap G2 between the second and third electrode pads 1010-2 and 1010-3. In some embodiments, the first optical resonator portion 1020-1 and the second optical resonator portion 1020-2 comprise ridge waveguide structures comprising respective lateral extensions 1021-1 and 1021-2. The lateral extensions 1021-1 of the first optical resonator portion 1020-1 are connected to the first and third electrode pads 1010-1 and 1010-3 of the RF resonator 1010. The lateral extensions 1021-2 of the second optical resonator portion 1020-2 are connected to the second and third electrode pads 1010-2 and 1010-3 of the RF resonator 1010.

The photonic crystal mirror 1030 comprises a partially reflective mirror which is configured to allow optical I/O signals to be input/output to/from one end of the optical resonator 1020 through photonic crystal mirror 1030. The photonic crystal mirrors 1031, 1032, and 1033 comprise fully reflective mirrors. The optical directional coupler 1022 is comprised of portions of the first and second optical transmission lines 1001 and 1002, and configured to enable coupling of optical signals between the first and second optical resonator portions 1020-1 and 1020-2 via adiabatic/evanescent coupling.

The optical resonator 1020 is configured to generate optical standing wave resonances of two optical wave signals along the optical resonator 1020 between the partially reflective photonic crystal mirror 1030 and the fully reflective photonic crystal mirror 1033. In some embodiments, as schematically illustrated in FIG. 10, the photonic crystal mirrors 1030 and 1031 comprise integrated Bragg reflectors that are constructed with elliptical holes that are etched in the first optical transmission line 1001 at the ends of the first optical resonator portion 1020-1, and the photonic crystal mirrors 1032 and 1033 comprise integrated Bragg reflectors that are constructed with elliptical holes that are etched in the second optical transmission line 1002 at the ends of the second optical resonator portion 1020-2. Collectively, the optical directional coupler 1022 and the fully reflective photonic crystal mirrors 1031 and 1032 are configured to optically couple ends of the first and second optical resonator portions 1020-1 and 1020-2 of the optical resonator 1020.

In some embodiments, the optical resonator 1020 is formed of electro-optic material (Pockels-effect material) which comprises an optical domain (mono-domain) that is permanently fixed in a desired orientation without the need to utilize a DC bias voltage (e.g., V_{Bias}) to achieve the electro-optic effect. For example, the optical resonator 1020 can be formed of lithium niobate (LiNbO₃), lithium tantalate (LiTaO₃), or other suitable materials which exhibit the electro-optic effect without the need for DC biasing.

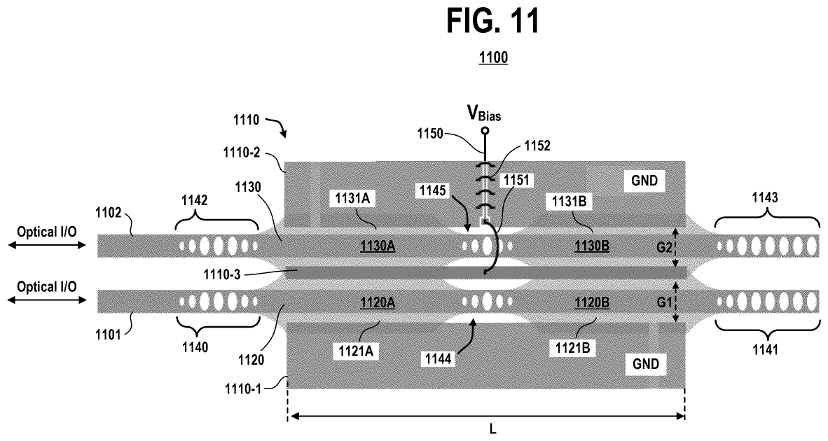

FIG. 11 schematically illustrates an EO transducer device, according to another exemplary embodiment of the disclosure. In particular, FIG. 11 schematically illustrates an EO transducer 1100 which comprises a first optical transmission line 1101 (or first optical waveguide), a second optical transmission line 1102 (or second optical waveguide), an RF resonator 1110, a first optical resonator 1120, a second optical resonator 1130, and photonic crystal mirrors 1140, 1141, 1142, 1143, 1144, and 1145. The RF resonator 1110 comprises a first electrode pad 1110-1, a second electrode pad 1110-2, and a third electrode pad 1110-3. The first, second, and third electrode pads 1110-1, 1110-2, and 1110-3 are metal/metallic electrodes with length L, and are disposed in a co-planar configuration (disposed on same X/Y plane), wherein the first and third electrode pads 1110-1 and 1110-3 are separated by a first electrode gap G1, and the second and third electrode pads 1110-2 and 1110-3 are separated by a second electrode gap G2. The gap sizes of the first and second electrode gaps G1 and G2 are designed to optimize an efficiency of the optical-RF transduction process.

The EO transducer 1100 comprises a CPW architecture where the RF resonator 1110 comprises a CPW resonator in which the third electrode pad 1110-3 (which corresponds to a CPW center conductor or signal line) is disposed between the first and second electrode pads 1110-1 and 1110-2 (which correspond to CPW ground conductors). In addition, as schematically illustrated in FIG. 11, the ends of the first, second and third electrode pads 1110-1, 1110-2, and 1110-3 are open-ended such that the RF resonator 1110 comprises an open end resonator in which the length L of the RF resonator 1110 is designed to be λ/2 (or smaller) of a target RF signal having a fundamental operating frequency ω_{RF} (i.e., L≤0.5 λ_{RF}). In this regard, the RF resonator 1110 comprises voltage-wave distributions (RF_{Mode}) of an RF signal (fundamental frequency ω_{RF}) along the length of the RF resonator 1110 in which the RF signal is maximum at the ends of the RF resonator 1110, and minimum at a mid-point of the RF resonator 1110. The first, second, and third electrode pads 1110-1, 1110-2, and 1110-3 can be formed of any type of metal or metallic material which is suitable for the given application (e.g., superconducting metal or otherwise). While not specifically shown in FIG. 11, it is to be noted that RF I/O can be implemented using any suitable one of the RF coupling mechanisms discussed above in conjunction with FIGS. 9A-9D.

It is to be noted that the first and second optical resonators 1120 and 1130 have structural configurations which are the same or similar to the structural configuration of the optical resonator 420 of FIG. 4A. In particular, the first optical resonator 1120 comprises a portion of the first optical transmission line 1101, which is disposed in the first gap G1 between the first and third electrode pads 1110-1 and 1110-3 of the RF resonator 1110. The first optical resonator 1120 comprises a first optical resonator portion 1120A and a second optical resonator portion 1120B. The first optical resonator portion 1120A is disposed between the photonic crystal mirrors 1140 and 1144, and the second optical resonator portion 1120B is disposed between the photonic crystal mirrors 1141 and 1144. In some embodiments, the first optical resonator portion 1120A and the second optical resonator portion 1120B comprise ridge waveguide structures comprising respective lateral extensions 1121A and 1121B. The lateral extensions 1121A of the first optical resonator portion 1120A are connected to the first and third electrode pads 1110-1 and 1110-3 of the RF resonator 1110. Similarly, the lateral extensions 1121B of the second optical resonator portion 1120B are connected to the first and third electrode pads 1110-1 and 1110-3 of the RF resonator 1110.

The photonic crystal mirrors 1140 and 1144 comprise partially reflective mirrors, and the photonic crystal mirror 1141 comprises a fully reflective mirror. The photonic crystal mirrors 1140 and 1141 are disposed at end portions of the first optical resonator 1120, and are configured to generate optical standing wave resonances of two optical signals along the first optical resonator 1120. The photonic crystal mirror 1144 (e.g., partially reflective mirror) is disposed in a middle region of the first optical resonator 1120, where the electric field amplitude (along the RF resonator 1110) is zero (0) or near zero. Similar to the exemplary embodiments discussed above, the photonic crystal mirror 1144 can be designed to compensate for moderate-to-strong mismatch between microwave and optical indices by introducing an optical phase shift φ_{Opt} at a mid-point of the first optical resonator 1120 to compensate for an intrinsic wavelength mismatch between λ_{RF} and λ_{beat} of the standing waves of the optical resonant signals in the first optical resonator 1120.

Similarly, the second optical resonator 1130 comprises a portion of the second optical transmission line 1102, which is disposed in the second gap G2 between the second and third electrode pads 1110-2 and 1110-3 of the RF resonator 1110. The second optical resonator 1130 comprises a first optical resonator portion 1130A and a second optical resonator portion 1130B. The first optical resonator portion 1130A is disposed between the photonic crystal mirrors 1142 and 1145, and the second optical resonator portion 1130B is disposed between the photonic crystal mirrors 1143 and 1145. In some embodiments, the first optical resonator portion 1130A and the second optical resonator portion 1130B comprise ridge waveguide structures comprising respective lateral extensions 1131A and 1131B. The lateral extensions 1131A of the first optical resonator portion 1130A are connected to the second and third electrode pads 1110-2 and 1110-3 of the RF resonator 1110. Similarly, the lateral extensions 1131B of the second optical resonator portion 1120B are connected to the second and third electrode pads 1110-2 and 1010-3 of the RF resonator 1110.

The photonic crystal mirrors 1142 and 1145 comprise partially reflective mirrors, and the photonic crystal mirror 1143 comprises a fully reflective mirror. The photonic crystal mirrors 1142 and 1143 are disposed at end portions of the second optical resonator 1130, and are configured to generate optical standing wave resonances of two optical signals along the second optical resonator 1130. The photonic crystal mirror 1145 (e.g., partially reflective mirror) is disposed in a middle region of the second optical resonator 1130, where the electric field amplitude (along the RF resonator 1110) is zero (0) or near zero. Similar to the exemplary embodiments discussed above, the photonic crystal mirror 1145 can be designed to compensate for moderate-to-strong mismatch between microwave and optical indices by introducing an optical phase shift φ_{Opt} at a mid-point of the second optical resonator 1130 to compensate for an intrinsic wavelength mismatch between λ_{RF} and λ_{beat} of the standing waves of the optical resonant signals in the second optical resonator 1130.

Moreover, as schematically illustrated in FIG. 11, a DC bias line 1150 extends through a void that is patterned in a middle region of the second electrode pad 1110-2 of the RF resonator 1110. The DC bias line 1150 is galvanically connected to a midpoint of the third electrode pad 1110-3 of the RF resonator 1110 via a jumper wire 1151 (e.g., airbridge connection), whereby a DC bias voltage V_{Bias} can be applied to the midpoint of the third electrode pad 1110-3. As in other embodiments of EO transducers discussed above, the DC bias voltage V_{Bias} is utilized in instances where the first and second optical resonators 1120 and 1130 are formed of material (e.g., barium titanate) that is DC-biased to achieve an electro-optic effect. The DC bias line 1150 extends through the patterned void in the middle region of the second electrode pad 1110-2 where the electric field amplitude along the RF resonator 1110 is zero (0) or near zero to prevent perturbance of the RF signal and prevent coupling of the RF signal to the DC bias line 1150. As further schematically illustrated in FIG. 11, a plurality of jumper wires 1152 (e.g., airbridge connections) are utilized to connect the inner edges of the second electrode pad 1110-2 adjacent to the void region through which the DC bias line 1150 extends.

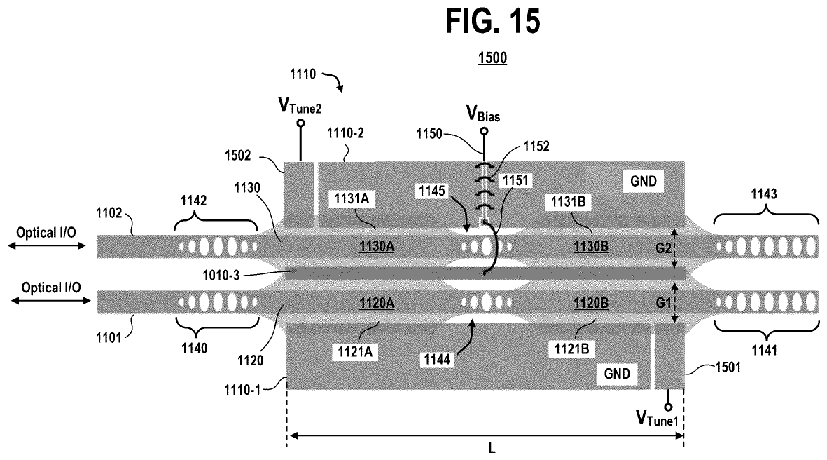

It is to be appreciated that the EO transducer 1100 comprises a compact architecture in which the first and second optical resonators 1120 and 1130 commonly share the same RF resonator 1110, and can be operated independently of each other for different optical signal channels (i.e., two independent optical signals interacting with one microwave mode). Moreover, in other embodiments, for quantum computing applications, the EO transducer 1100 can be configured to perform entanglement operations between quantum bits. In particular, the EO transducer 1100 may be configured as an entangled photon source for remote entanglement. For example, the RF resonator 1110 can be loaded with a single microwave photon from, e.g., a quantum bit, wherein the single microwave photon is converted into an optical signal in the first optical resonator 1120 or the second optical resonator 1130 with 50% probability. The probabilities can be matched with optical pump power. Moreover, the optical frequencies can be matched using a separate DC tuning voltage for each device (see FIG. 15).

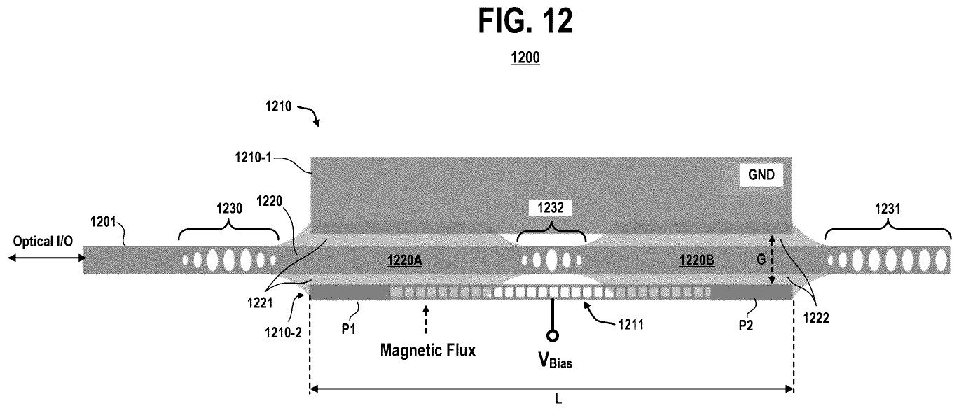

FIG. 12 schematically illustrates an EO transducer device, according to another exemplary embodiment of the disclosure. In particular, FIG. 12 schematically illustrates an EO transducer 1200 which comprises an optical transmission line 1201 (or optical waveguide), an RF resonator 1210, an optical resonator 1220, and photonic crystal mirrors 1230, 1231, and 1232. The RF resonator 1210 comprises a first electrode pad 1210-1 and a second electrode pad 1210-2. The second electrode pad 1210-2 comprises a kinetic inductance ladder resonator 1211 (alternatively, ladder resonator 1211) which is connected to and between a first pad P1 and a second pad P2, wherein the ladder resonator 1211 is implemented to provide a tunable EO transducer architecture. The first and second electrode pads 1210-1 and 1210-2 are metal/metallic electrodes with length L, and are disposed in a co-planar configuration (disposed on same X/Y plane), and separated by an electrode gap G where the size of the gap G is designed to optimize an efficiency of the optical-RF transduction process.

The RF resonator 1210 comprises an open-ended resonator in which the length L of the RF resonator 1210 is designed to be λ/2 (or smaller) of a target RF signal having a fundamental operating frequency ω_{RF} (i.e., L≤0.5 λ_{RF}). In this regard, the RF resonator 1210 comprises a voltage-wave distribution (RF_{Mode}) of an RF signal (fundamental frequency ω_{RF}) along the length of the RF resonator 1210 in which the RF signal is maximum at the ends of the RF resonator 1210, and minimum at a mid-point of the RF resonator 1210. The first and second electrode pads 1210-1 and 1210-2 can be formed of any type of metal or metallic material which is suitable for the given application (e.g., superconducting metal or otherwise). While not specifically shown in FIG. 12, it is to be noted that RF I/O can be implemented using any suitable one of the RF coupling mechanisms discussed above in conjunction with FIGS. 9A-9D.

The optical resonator 1220 has a structural configuration which is the same or similar to the structural configuration of the optical resonator 420 of FIG. 4A. In particular, the optical resonator 1220 comprises a portion of the optical transmission line 1201, which is disposed in the gap G between the first and second electrode pads 1210-1 and 1210-2 of the RF resonator 1210. The optical resonator 1220 comprises a first optical resonator portion 1220A and a second optical resonator portion 1220B. The first optical resonator portion 1220A is disposed between the photonic crystal mirrors 1230 and 1232, and the second optical resonator portion 1220B is disposed between the photonic crystal mirrors 1231 and 1232. In some embodiments, the first optical resonator portion 1220A and the second optical resonator portion 1220B comprise ridge waveguide structures comprising respective lateral extensions 1221 and 1222. The lateral extensions 1221 of the first optical resonator portion 1220A are connected to the first and second electrode pads 1210-1 and 1210-2 of the RF resonator 1210. Similarly, the lateral extensions 1222 of the second optical resonator portion 1220B are connected to the first and second electrode pads 1210-1 and 1210-2 of the RF resonator 1210.

The photonic crystal mirrors 1230 and 1232 comprise partially reflective mirrors, and the photonic crystal mirror 1231 comprises a fully reflective mirror. The photonic crystal mirrors 1230 and 1231 are disposed at end portions of the optical resonator 1220, and are configured to generate optical standing wave resonances of two optical signals along the optical resonator 1220. The photonic crystal mirror 1232 (e.g., partially reflective mirror) is disposed in a middle region of the optical resonator 1220, where the electric field amplitude (along the RF resonator 1210) is zero (0) or near zero. Similar to the exemplary embodiments discussed above, the photonic crystal mirror 1232 can be designed to compensate for moderate-to-strong mismatch between microwave and optical indices by introducing an optical phase shift φ_{Opt} at a mid-point of the optical resonator 1220 to compensate for an intrinsic wavelength mismatch between λ_{RF} and λ_{beat} of the standing waves of the optical resonant signals in the optical resonator 1220.

Moreover, as schematically illustrated in FIG. 12, a DC bias voltage V_{Bias} is applied to a midpoint of the second electrode pad 1210-2 of the RF resonator 1210 in instances where the optical resonator 1220 is formed of a material (e.g., barium titanate) that is DC-biased to achieve an electro-optic effect. The DC bias voltage V_{Bias} is applied by a DC bias line that is galvanically connected to a middle region of the second electrode pad 1210-2 where the electric field amplitude along the RF resonator 1210 is zero (0) or near zero to prevent perturbance of the RF signal and prevent coupling of the RF signal to the DC bias line.

The ladder resonator 1211 comprises a flux-tunable inductive element which comprises an inductance that can be tuned by applying a magnetic flux to the ladder resonator 1211 to thereby enable field-tuning of an RF resonance of the RF resonator 1210. The exemplary configuration of the EO transducer 1200 shown in FIG. 12 is similar to the configuration of the EO transducer 500 of FIG. 5A, but where the SQUID 520 in FIG. 5A is replaced by the ladder resonator 1211 to enable field-tuning of the EO transducer 1200 by effectively changing the inductance of the RF resonator 1210. With this exemplary configuration, applying a magnetic flux to the ladder resonator 1211 induces circular currents that flow in the ladder resonator 1211, which effectively changes the inductance of the RF resonator 1210.

In some embodiments, the magnetic flux applied to the ladder resonator 1211 (for tuning the inductance of the RF resonator 1210) comprises an external magnetic field that is generated off-chip by a magnetic coil structure. In other embodiments, the magnetic flux applied to the ladder resonator 1211 is generated on-chip using suitable techniques, e.g., applying DC tuning current to a flux line or inductor that is disposed adjacent to the ladder resonator 1211 to generate a magnetic flux or mutual inductance that is applied to the ladder resonator 1211.

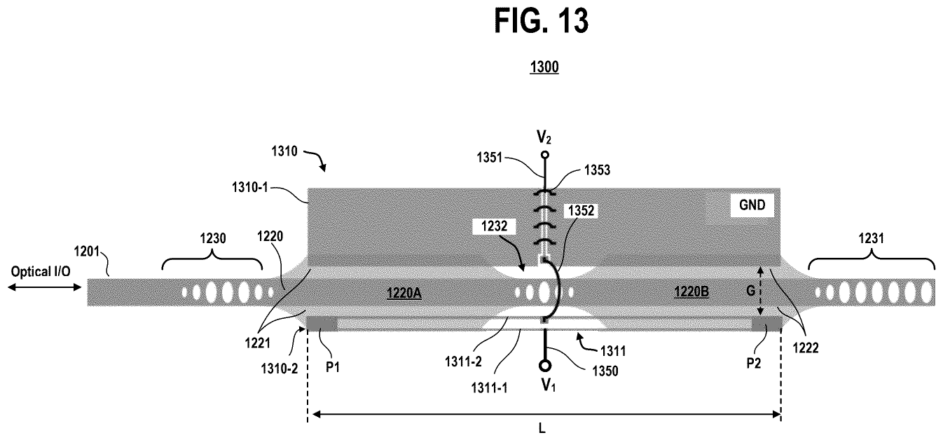

FIG. 13 schematically illustrates an EO transducer device, according to another exemplary embodiment of the disclosure. In particular, FIG. 13 schematically illustrates an EO transducer 1300 having a tunable EO transducer architecture for tuning a resonant frequency of an RF resonator 1310. The EO transducer 1300 has an optical resonator framework which is the same or similar to the EO transducer 1200 of FIG. 12, the details of which will not be repeated, but implements a different RF resonator framework for tuning an inductance of the RF resonator 1310. As schematically shown in FIG. 13, the RF resonator 1310 comprises a first electrode pad 1310-1 and a second electrode pad 1310-2. The second electrode pad 1310-2 comprises a kinetic inductance wire resonator 1311 which is connected to and between a first pad P1 and a second pad P2. The kinetic inductance wire resonator 1311 is implemented to provide a tunable EO transducer architecture in which an inductance of the RF resonator 1310 is tuned by applying a voltage differential to the kinetic inductance wire resonator 1311.

Similar to other RF resonators discussed above, the RF resonator 1310 comprises an open-ended resonator in which the length L of the RF resonator 1310 is designed to be λ/2 (or smaller) of a target RF signal having a fundamental operating frequency ω_{RF} (i.e., L≤0.5 λ_{RF}). In this regard, the RF resonator 1310 comprises a voltage-wave distribution (RF_{Mode}) of an RF signal (fundamental frequency ω_{RF}) along the length of the RF resonator 1310 in which the RF signal is maximum at the ends of the RF resonator 1310, and minimum at a mid-point of the RF resonator 1310. The first and second electrode pads 1310-1 and 1310-2 can be formed of any type of metal or metallic material which is suitable for the given application (e.g., superconducting metal or otherwise). While not specifically shown in FIG. 13, it is to be noted that RF I/O can be implemented using any suitable one of the RF coupling mechanisms discussed above in conjunction with FIGS. 9A-9D.

The kinetic inductance wire resonator 1311 comprises a first wire 1311-1 and a second wire 1311-2, which are disposed in parallel and connected to and between the first and second pads P1 and P2. The first wire 1311-1 is galvanically connected to a first DC bias voltage line 1350, to apply a first DC bias voltage V₁ to the first wire 1311-1. The second wire 1311-2 is galvanically connected to a second DC bias voltage line 1351 via a jumper wire 1352 (e.g., airbridge connection), to apply a second DC bias voltage V₂ to the second wire 1311-2. The second DC bias voltage line 1351 extends through a void that is patterned in a middle region of the first electrode pad 1310-1 of the RF resonator 1310. A plurality of jumper wires 1353 (e.g., airbridge connections) are utilized to connect the inner edges of the first electrode pad 1310-1 adjacent to the void region through which the second DC bias voltage line 1351 extends. The first and second DC bias voltage lines 1350 and 1351 and the jumper wire 1352 are disposed in a middle region of the RF resonator 1310 where the electric field amplitude along the RF resonator 1310 is zero (0) or near zero to prevent perturbance of the RF signal and prevent coupling of the RF signal to the first and second DC bias voltage lines 1350 and 1351.

As in other embodiments of EO transducers discussed above, the first and second DC bias voltages V₁ and V₂ are utilized in instances where the optical resonator 1220 is formed of material (e.g., barium titanate) that is DC-biased to achieve an electro-optic effect. For DC biasing of the optical material, the first and second DC bias voltages V₁ and V₂ have equal voltages (V_{Bias}=V₁=V₂). On the other hand, for frequency tuning, a small voltage differential between V₁ and V₂, ΔV_{Tune}=|V₁−V₂|, is applied to cause DC current flow through the kinetic inductance wire resonator 1311 to change and inductance of the RF resonator 1310 and thereby tune the resonant frequency of the RF resonator 1310. In this regard, the kinetic inductance wire resonator 1311 comprises a voltage-tunable inductive element which comprises an inductance that can be tuned by applying a voltage differential to the first and second wires 1311-1 and 1311-2 of the kinetic inductance wire resonator 1311.

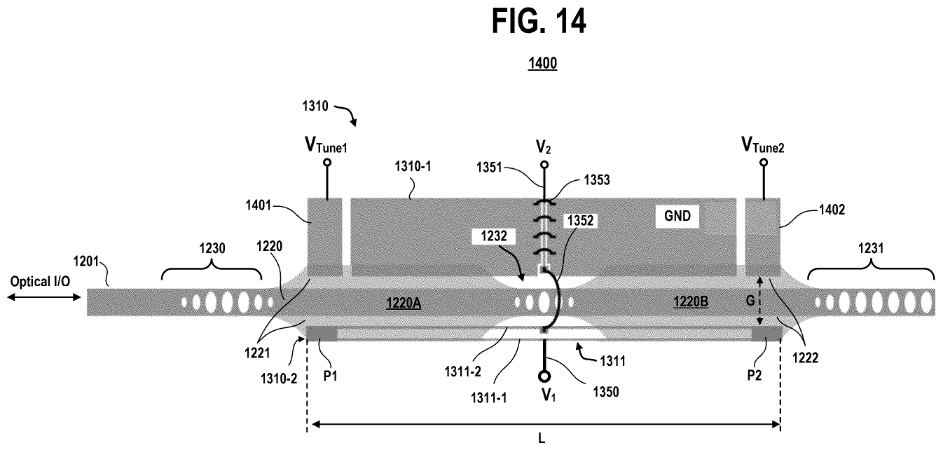

FIG. 14 schematically illustrates an EO transducer device, according to another exemplary embodiment of the disclosure. In particular, FIG. 14 schematically illustrates an EO transducer 1400 which is similar in structure and operation to the EO transducer 1300 of FIG. 13 as discussed above. However, the EO transducer 1400 comprises a tunable EO transducer architecture that enables (i) voltage-tuning of the RF resonant frequency of the RF resonator 1310, as well as (ii) voltage-tuning of the optical resonant frequencies of the optical resonator 1220. In particular, the EO transducer 1400 further comprises a first tuning electrode 1401 and a second tuning electrode 1402, which are capacitively coupled to, and collectively form, the first electrode pad 1310-1 of the RF resonator 1310. The first tuning electrode 1401 is connected to the lateral extension 1221 of the first optical resonator portion 1220A of the optical resonator 1220. The second tuning electrode 1402 is connected to the lateral extension 1222 of the second optical resonator portion 1220B of the optical resonator 1220. Moreover, as further shown in FIG. 14, a first DC tuning voltage (V_{Tune1}) can be applied to the first tuning electrode 1401 which, in turn, is applied to the lateral extension 1221 of the first optical resonator portion 1220A for selectively tuning the first optical resonator portion 1220A of the EO transducer 1400. Similarly, a second DC tuning voltage (V_{Tune2}) can be applied to the second tuning electrode 1402 which, in turn, is applied to the lateral extension 1222 of the second optical resonator portion 1220B for selectively tuning the second optical resonator portion 1220B of the EO transducer 1400.

As noted above, such selective tuning is particularly advantageous in operating regimes of the EO transducer 1400 (such as discussed above in conjunction with FIG. 5D) where, for example, the EO transducer 1400 is relatively small in length (e.g., L<<0.5 λ_{RF}), and the photonic crystal mirror 1232 is designed to have strong reflection properties to achieve a desired optical phase shift φ_{Opt} to compensate for the intrinsic wavelength mismatch between λ_{RF} and λ_{beat}. In such operating regimes, the optical resonator 1220 effectively comprises two separate optical resonators (e.g., the first optical resonator portion 1220A and the second optical resonator portion 1220B) that are weakly coupled through the photonic crystal mirror 1232, where it becomes critical for the first optical resonator portion 1220A and the second optical resonator portion 1220B to have the same resonant frequency (or substantially identical resonant frequencies) to enable optical interaction between the first and second optical resonator portions 1220A and 1220B. In this regard, the first and second tuning electrodes 1401 and 1402 are configured to apply respective first and second tuning voltage V_{Tune1} and V_{Tune2} to the respective first and second optical resonator portions 1220A and 1220B, as needed, to achieve optical resonance frequency matching between the first and second optical resonator portions 1220A and 1220B of the optical resonator 1220. While not specifically shown in FIG. 14, it is to be noted that RF I/O can be implemented using any suitable one of the RF coupling mechanisms discussed above in conjunction with FIGS. 9A-9D.

FIG. 15 schematically illustrates an EO transducer device, according to another exemplary embodiment of the disclosure. In particular, FIG. 15 schematically illustrates an EO transducer 1500 which is similar in structure and operation to the CPW-based EO transducer 1100 of FIG. 11 as discussed above, the details of which will not be repeated. However, the EO transducer 1500 comprises a tunable EO transducer architecture that enables voltage-tuning of the optical resonant frequencies of the first and second optical resonators 1120 and 1130. In particular, the EO transducer 1500 comprises a first tuning electrode 1501 and a second tuning electrode 1502. The first tuning electrode 1501 is capacitively coupled to, and collectively forms, the first electrode pad 1110-1 of the RF resonator 1110. The first tuning electrode 1501 is connected to the lateral extension 1121B of the second optical resonator portion 1120B of the first optical resonator 1120. The second tuning electrode 1502 is connected to the lateral extension 1131A of the first optical resonator portion 1130A of the second optical resonator 1130.

Moreover, as further shown in FIG. 15, a first DC tuning voltage (V_{Tune1}) can be applied to the first tuning electrode 1501 which, in turn, is applied to the lateral extension 1121B of the second optical resonator portion 1120B for selectively tuning the second optical resonator portion 1120B of the first optical resonator 1120 of the EO transducer 1500. Similarly, a second DC tuning voltage (V_{Tune2}) can be applied to the second tuning electrode 1502 which, in turn, is applied to the lateral extension 1131A of the first optical resonator portion 1130A of the second optical resonator 1130 for selectively tuning the first optical resonator portion 1130A of the second optical resonator 1130 of the EO transducer 1500. As with the exemplary embodiments discussed above, the first DC tuning voltage (V_{Tune1}) can be applied to tune the optical resonant frequency of the second optical resonator portion 1120B of the first optical resonator 1120 to match the optical resonant frequency of the first optical resonator portion 1120A of the first optical resonator 1120, and the second DC tuning voltage (V_{Tune2}) can be applied to tune the optical resonant frequency of the first optical resonator portion 1130A of the second optical resonator 1130 to match the optical resonant frequency of the second optical resonator portion 1130B of the second optical resonator 1130. While not specifically shown in FIG. 15, it is to be noted that RF I/O can be implemented using any suitable one of the RF coupling mechanisms discussed above in conjunction with FIGS. 9A-9D.

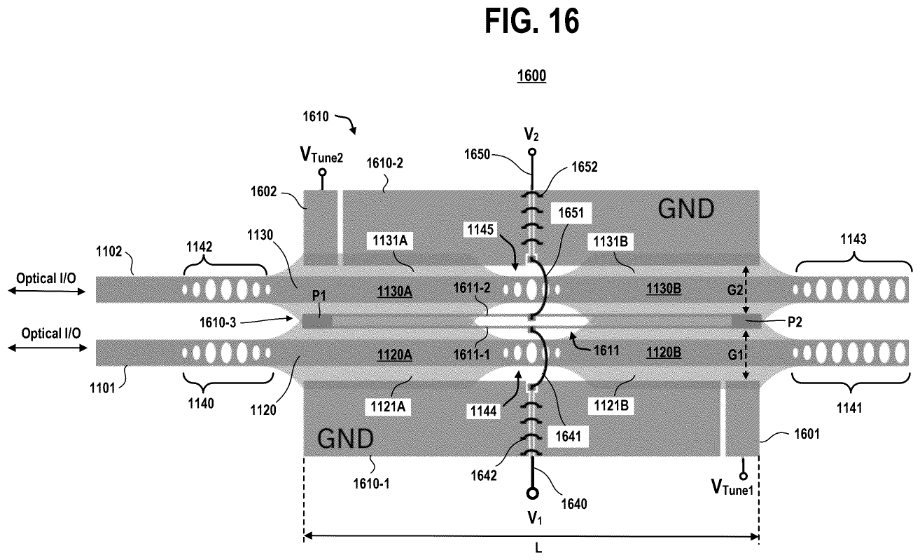

FIG. 16 schematically illustrates an EO transducer device, according to another exemplary embodiment of the disclosure. In particular, FIG. 16 schematically illustrates an EO transducer 1600 which is similar in structure and operation to the CPW-based EO transducers 1100 and 1500 of FIGS. 11 and 15 as discussed above, the details of which will not be repeated. However, the EO transducer 1600 comprises an RF resonator 1610 which is configured to enable (i) voltage-tuning of the RF resonant frequency of the RF resonator 1610, as well as (ii) voltage-tuning of the optical resonant frequencies of the first and second optical resonators 1120 and 1130.

In particular, the RF resonator 1610 comprises a first electrode pad 1610-1, a second electrode pad 1610-2, a third electrode pad 1610-3, a first tuning electrode 1601, and a second tuning electrode 1602. The RF resonator 1610 comprises an open-end CPW-based resonator architecture in which (i) the first electrode pad 1610-1 comprises a first outer conductor of the CPW resonator, (ii) the second electrode pad 1610-2 comprises a second outer conductor of the CPW resonator, and (iii) the third electrode pad 1610-3 forms a center conductor of the CPW resonator.

The RF resonator 1610 comprises an open-end resonator in which the length L of the RF resonator 1610 is designed to be λ/2 (or smaller) of a target RF signal having a fundamental operating frequency ω_{RF} (i.e., L≤0.5 λ_{RF}). In this regard, the RF resonator 1610 comprises voltage-wave distributions (RF_{Mode}) of an RF signal (fundamental frequency ω_{RF}) along the length of the RF resonator 1610 in which the RF signal is maximum at the ends of the RF resonator 1610, and minimum at a mid-point of the RF resonator 1610. The first, second, and third electrode pads 1610-1, 1610-2, and 1610-3, and the first and second tuning electrodes 1601 and 1602 can be formed of any type of metal or metallic material which is suitable for the given application (e.g., superconducting metal or otherwise). While not specifically shown in FIG. 16, it is to be noted that RF I/O can be implemented using any suitable one of the RF coupling mechanisms discussed above in conjunction with FIGS. 9A-9D.

The first tuning electrode 1601 and the second tuning electrode 1602 are utilized to apply respective first and second tuning voltages V_{Tune1} and V_{Tune2} to portions of the respective first and second optical resonators 1120 and 1130 to selectively tune optical resonant frequencies thereof, using the exemplary tuning methods as discussed above, the details of which need not be repeated. The third electrode pad 1610-3 comprises a kinetic inductance wire resonator 1611 which is connected to and between a first pad P1 and a second pad P2. Similar to the exemplary tuning architecture of the EO transducer 1400 discussed above in conjunction with FIG. 14, the EO transducer 1600 of FIG. 16 implements the kinetic inductance wire resonator 1611 to provide a tunable EO transducer architecture in which an inductance of the RF resonator 1610 can be tuned by applying a voltage differential to the kinetic inductance wire resonator 1611.

As schematically illustrated in FIG. 16, the kinetic inductance wire resonator 1611 comprises a first wire 1611-1 and a second wire 1611-2, which are disposed in parallel and connected to and between the first and second pads P1 and P2. The first wire 1611-1 is galvanically connected to a first DC bias voltage line 1640 via a jumper wire 1641 (e.g., airbridge connection), to apply a first DC bias voltage V₁ to the first wire 1611-1. The first DC bias voltage line 1640 extends through a void that is patterned in a region of the first electrode pad 1610-1 which is aligned to a central (symmetry) point of the RF resonator 1610. A plurality of jumper wires 1642 (e.g., airbridge connections) are utilized to connect the inner edges of the first electrode pad 1610-1 adjacent to the void region through which the first DC bias voltage line 1640 extends. Similarly, the second wire 1611-2 is galvanically connected to a second DC bias voltage line 1650 via a jumper wire 1651 (e.g., airbridge connection), to apply a second DC bias voltage V₂ to the second wire 1611-2. The second DC bias voltage line 1650 extends through a void that is patterned in a region of the second electrode pad 1610-2 which is aligned to a central (symmetry) point of the RF resonator 1610. A plurality of jumper wires 1652 (e.g., airbridge connections) are utilized to connect the inner edges of the second electrode pad 1610-2 adjacent to the void region through which the second DC bias voltage line 1650 extends. The first and second DC bias voltage lines 1640 and 1650 and the jumper wires 1641 and 1651 are disposed in a middle region of the RF resonator 1610 where the electric field amplitude along the RF resonator 1610 is zero (0) or near zero to prevent perturbance of the RF signal and prevent coupling of the RF signal to the first and second DC bias voltage lines 1640 and 1650.

As in other embodiments of EO transducers discussed above, the first and second DC bias voltages V₁ and V₂ are utilized in instances where the first and second optical resonators 1120 and 1130 are formed of an optical material (e.g., barium titanate) that is DC-biased to achieve an electro-optic effect. For DC biasing of the optical material, the first and second DC bias voltages V₁ and V₂ have equal voltages (V_{Bias}=V₁=V₂). On the other hand, for frequency tuning, a small voltage differential between V₁ and V₂, ΔV_{Tune}=|V₁−V₂|, is applied to cause DC current flow through the kinetic inductance wire resonator 1611 to change the inductance of the RF resonator 1610 and thereby tune the resonant frequency of the RF resonator 1610. In this regard, the kinetic inductance wire resonator 1611 comprises a voltage-tunable inductive element which comprises an inductance that can be tuned by applying a voltage differential to the first and second wires 1611-1 and 1611-2 of the kinetic inductance wire resonator 1611.

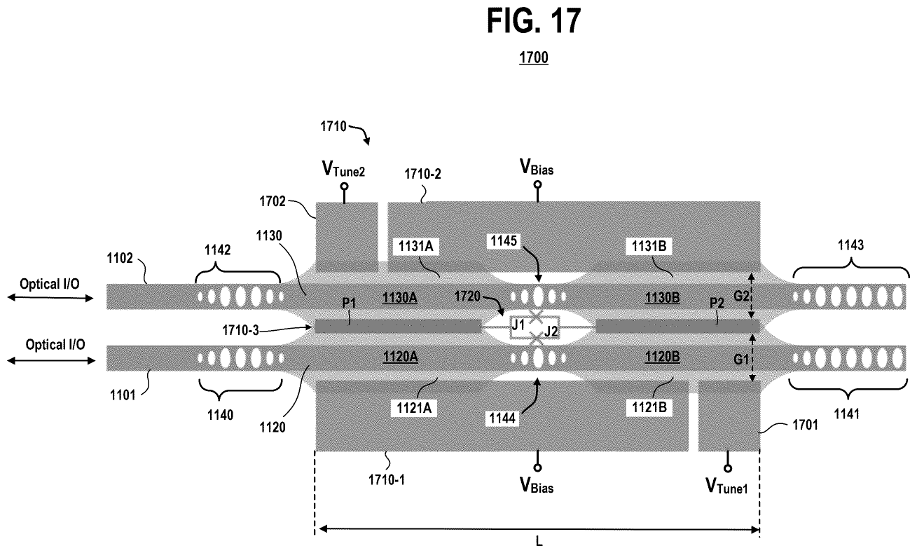

FIG. 17 schematically illustrates an EO transducer device, according to another exemplary embodiment of the disclosure. In particular, FIG. 17 schematically illustrates an EO transducer 1700 which is similar in structure and operation to the CPW-based EO transducers 1100 and 1600 of FIGS. 11 and 16 as discussed above, the details of which will not be repeated. The EO transducer 1700 comprises an alternate embodiment of a RF resonator 1710 which is configured to enable (i) voltage-tuning of the RF resonant frequency of the RF resonator 1710, as well as (ii) voltage-tuning of the optical resonant frequencies of the first and second optical resonators 1120 and 1130.

In particular, the RF resonator 1710 comprises a first electrode pad 1710-1, a second electrode pad 1710-2, a third electrode pad 1710-3, a first tuning electrode 1701, and a second tuning electrode 1702. The RF resonator 1710 comprises an open-end CPW-based resonator architecture in which (i) the first electrode pad 1710-1 comprises a first outer conductor of the CPW resonator, (ii) the second electrode pad 1710-2 comprises a second outer conductor of the CPW resonator, and (iii) the third electrode pad 1710-3 forms a center conductor of the CPW resonator.

The RF resonator 1710 comprises an open-end resonator in which the length L of the RF resonator 1710 is designed to be λ/2 (or smaller) of a target RF signal having a fundamental operating frequency ω_{RF} (i.e., L≤0.5 λ_{RF}). In this regard, the RF resonator 1710 comprises voltage-wave distributions (RF_{Mode}) of an RF signal (fundamental frequency ω_{RF}) along the length of the RF resonator 1710 in which the RF signal is maximum at the ends of the RF resonator 1710, and minimum at a mid-point of the RF resonator 1710. The first, second, and third electrode pads 1710-1, 1710-2, and 1710-3, and the first and second tuning electrodes 1701 and 1702 can be formed of any type of metal or metallic material which is suitable for the given application (e.g., superconducting metal or otherwise). While not specifically shown in FIG. 17, it is to be noted that RF I/O can be implemented using any suitable one of the RF coupling mechanisms discussed above in conjunction with FIGS. 9A-9D.

As in other embodiments of EO transducers discussed above, in instances where the first and second optical resonators 1120 and 1130 are formed of an optical material (e.g., barium titanate) that is DC-biased to achieve an electro-optic effect, a DC bias voltage is applied to the first and second electrode pads 1710-1 and 1710-2 at a central (symmetry) point of the RF resonator 1710 where the RF field is zero (0) or close to zero. In addition, the first tuning electrode 1701 and the second tuning electrode 1702 are utilized to apply respective first and second tuning voltages V_{Tune1} and V_{Tune2} to portions of the respective first and second optical resonators 1120 and 1130 to selectively tune optical resonant frequencies thereof, using the exemplary tuning methods as discussed above, the details of which need not be repeated.

The third electrode pad 1710-3 comprises a first pad P1 and a second pad P2, and a SQUID 1720 that is connected to and between the first pad P1 and the second pad P2. The SQUID 1720 comprises a superconducting loop formed by a parallel connection of first and second Josephson junctions J1 and J2. The first pad P1 is connected to the lateral extensions 1121A and 1131A of the respective first optical resonator portions 1120A and 1130A of the respective first and second optical resonators 1120 and 1130. The second pad P2 is connected to the lateral extensions 1121B and 1131B of the respective second optical resonator portions 1120B and 1130B of the respective first and second optical resonators 1120 and 1130. In the exemplary configuration of FIG. 17, the SQUID 1720 is an inductive element which has an effective inductance (based on the non-linear inductance of the Josephson junctions J1 and J2) which can be tuned by passing a magnetic flux through the superconducting loop of the SQUID 1720 using known techniques to selectively tune the inductance of the RF resonator 1710 and, thus, tune the RF resonant frequency of the RF resonator 1710.

It is to be appreciated that the exemplary triply resonant EO transducer architectures as discussed herein eliminate the use of ring-based triply resonant EO transducer structures, and avoid the disadvantage and limitations associated therewith. For example, the exemplary triply resonant EO transducers as described herein do not include ring structures, provide reduced footprints, allow reduced circuit design complexity, enable a natural integration of the optics with a microwave circuit, enable use of an ideal crystal orientation, and do not rely on directional couplers for frequency matching. Instead, frequency matching and phase matching are achieved by engineering a lithographically patterned tunable mirror element (or compensation mirror) that is disposed within an optical resonator. The properties of the compensation mirror can be designed and optimized independently of the slab/ridge height of the optical waveguide and does not depend on any bending losses or so. Indeed, shifting the fabrication tolerance requirements from tight gaps in the directional coupler and the exact ridge/slab heights, to photonic crystal patterning to construct compensation mirrors, provides a much larger freedom to engineer robust and fabrication-tolerant designs. Moreover, as shown in the exemplary embodiments of FIGS. 6, 7A and 7B, increased bus coupling flexibility can be realized by utilizing standard evanescent directional couplers to couple optical signals between an optical resonator and an optical transmission line (or optical bus), and in addition, optical coupling can be realized through partially reflective photonic mirrors, which is an even more compact and simple “inline” solution.

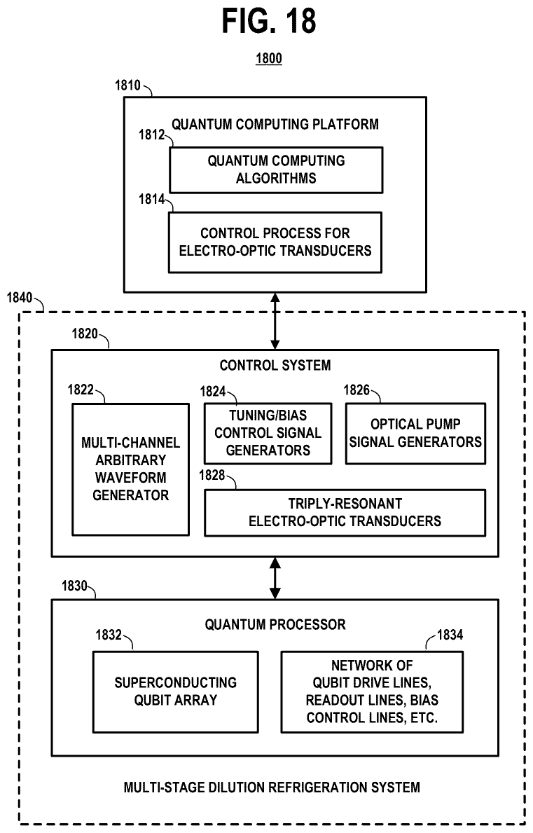

FIG. 18 schematically illustrates a quantum computing system which implements electro-optic transducers to enable optical communication with remote quantum computing systems, according to an exemplary embodiment of the disclosure. In particular, FIG. 18 schematically illustrates a quantum computing system 1800 which comprises a quantum computing platform 1810, a control system 1820, and a quantum processor 1830 (or quantum processing unit (QPU)). In some embodiments, the quantum computing platform 1810 implements a software platform that is configured to program a quantum computer to execute quantum computing algorithms 1812 which are implemented using, e.g., quantum circuits that define computational routines consisting of coherent quantum operations on quantum data, such as qubits. In addition, in some embodiments, the quantum computing platform 1810 implements software control processes 1814 to control the operation of EO transducers, as discussed herein. In some embodiments, the quantum computing systems 110 in FIG. 1 can be implemented based on the exemplary architecture of the quantum computing system 1800 of FIG. 18.

In some embodiments, the control system 1820 comprises a multi-channel arbitrary waveform generator (AWG) 1822, tuning/bias control signal generators 1824, optical pump signal generators 1826, and electro-optical transducers 1828 (e.g., triply resonant EO transducers). The quantum processor 1830 comprises one or more solid-state quantum chips which collectively implement a superconducting qubit array 1832. The quantum processor 1830 further comprises a network 1834 of qubit drive lines, readout resonator lines, flux-bias control lines, etc., and other cQED components that may be needed for a given application or quantum system configuration.

In some embodiments, the control system 1820 and the quantum processor 1830 are disposed at different stages of a dilution refrigeration system 1840 which can generate cryogenic temperatures that are sufficient to operate components of the control system 1820 for quantum computing applications. For example, the quantum processor 1830 may need to be cooled down to near-absolute zero, e.g., 10-15 millikelvin (mK), to allow superconducting qubits and flux-tunable double transmon couplers to exhibit quantum behaviors. In some embodiments, the dilution refrigeration system 1840 comprises a multi-stage dilution refrigerator where the components of the control system 1820 can be maintained at different cryogenic temperatures, as needed. For example, while the quantum processor 1830 may need to be cooled down to, e.g., 10-15 mK, the circuit components of the control system 1820 may be operated at cryogenic temperatures greater than 10-15 mK (e.g., cryogenic temperatures in a range of 3K-4K), depending on the configuration of the quantum computing system. In other embodiments, some or all of the components of the control system 1820 are disposed and operated in a room temperature environment.

In some embodiments, the superconducting qubit array 1832 comprises a quantum system of superconducting qubits, tunable couplers, and other components commonly utilized to support quantum processing using qubits. The number of superconducting qubits of the superconducting qubit array 1832 can be on the order of tens, hundreds, thousands, or more, etc. The network 1834 of qubit drive lines, readout resonator lines, and flux bias control lines, etc., is coupled to the control system 1820 through a suitable hardware input/output (I/O) interface, which couples I/O and control signals between the control system 1820 and the quantum processor 1830. For example, the hardware I/O interface may comprise various types of hardware and components, such as RF cables, wiring, RF elements, optical fibers, heat exchangers, filters, amplifiers, isolators, etc.

In some embodiments, the multi-channel AWG 1822 and other suitable microwave pulse signal generators are configured to generate the microwave control pulses that are applied to the qubit drive lines to control the operation of the superconducting qubits when performing various gate operations to execute a given certain quantum information processing algorithm. The multi-channel AWG 1822 generates and selectively applies microwave control pulses to the qubit drive lines of respective superconducting qubits to change the quantum state of the superconducting qubits (e.g., change the quantum state of a given qubit between the ground state and excited state, or to a superposition state) when executing quantum information processing algorithms. In addition, the tuning/bias control signal generators 1824 generate flux-bias control signals that are applied to flux-bias control lines to selectively activate/deactivate the tunable couplers to perform multi-gate entanglement operations (e.g., two qubit gate operations) when executing quantum information processing algorithms. The tuning/flux-bias control signal generators 1824 are configured to apply DC bias and tuning voltages to the EO transducers 1828, as needed.

In some embodiments, the multi-channel AWG 1822 comprises a plurality of AWG channels, which control respective superconducting qubits within the superconducting qubit array 1832 of the quantum processor 1830. In some embodiments, each AWG channel comprises a baseband signal generator, a digital-to-analog converter (DAC) stage, a filter stage, a modulation stage, an impedance matching network, and a phase-locked loop system to generate local oscillator (LO) signals (e.g., quadrature LO signals LO_I and LO_Q) for the respective modulation stages of the respective AWG channels. In some embodiments, the multi-channel AWG 1822 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I (t) and Q (t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I (t) and Q (t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

The optical pump signal generators 1826 are configured to generate CW or pulsed optical carrier signals (optical pump signals) with target pump frequencies that are applied to the EO transducers 1828 to perform triply resonant transduction operations, as discussed above. The EO transducers 1828 can be constructed using any of the exemplary triply resonant EO transducer architectures as discussed above. Each EO transducer 1828 is configured, for example, to (i) convert a microwave signal, which is readout from a given quantum bit of the quantum processor, to an optical signal that is transmitted over an optical communications network, and (ii) convert an optical signal, which is received from the optical communications network, into a microwave signal that is utilized to change a state of a given quantum bit.

The quantum computing platform 1810 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 1810 comprises a hardware architecture of processors, memory, etc., which is configured to control the execution of quantum applications, and interface with the control system 1820 to (i) generate digital control signals that are converted to analog microwave control signals by the control system 1820, to control operations of the quantum processor 1830 when executing a given quantum application, and (ii) to obtain and process digital signals received from the control system 1820, which represent the processing results generated by the quantum processor 1830 when executing various gate operations for a given quantum application.

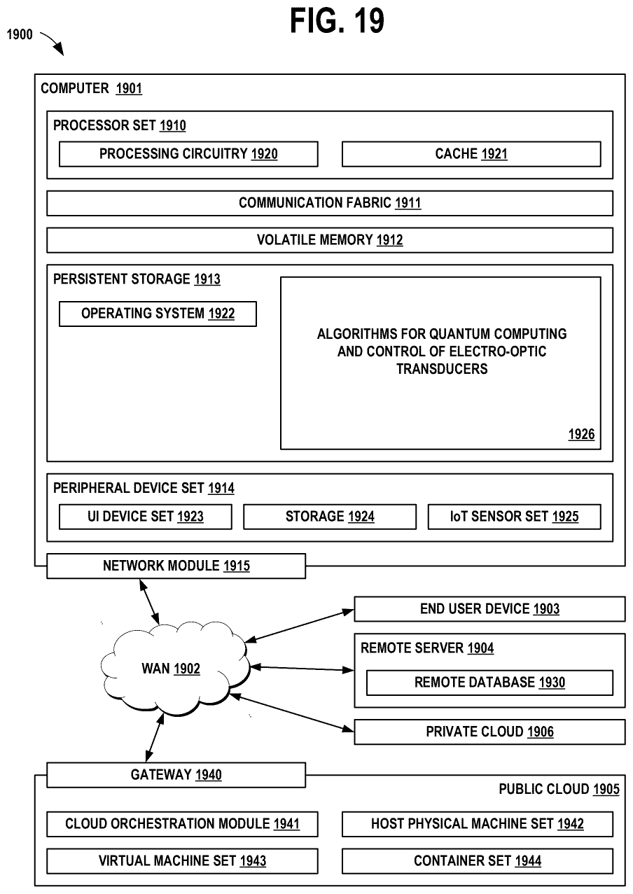

In some exemplary embodiments, the quantum computing platform 1810 of the quantum computing system 1800 may be implemented using any suitable computing system architecture (e.g., as shown in FIG. 19) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 19 schematically illustrates an exemplary architecture of a computing environment 1900 for hosting a quantum computing platform and performing quantum information processing, according to an exemplary embodiment of the disclosure. The computing environment 1900 of FIG. 19 contains an example of an environment for the execution of at least some of the computer code (block 1926) involved in executing, e.g., quantum computing algorithms, and control algorithms for controlling operation of triply resonant EO transducers, as discussed herein. In addition to block 1926, computing environment 1900 includes, for example, computer 1901, wide area network (WAN) 1902, end user device (EUD) 1903, remote server 1904, public cloud 1905, and private cloud 1906. In this embodiment, computer 1901 includes processor set 1910 (including processing circuitry 1920 and cache 1921), communication fabric 1911, volatile memory 1912, persistent storage 1913 (including operating system 1922 and block 1926, as identified above), peripheral device set 1914 (including user interface (UI) device set 1923, storage 1924, and Internet of Things (IoT) sensor set 1925), and network module 1915. Remote server 1904 includes remote database 1930. Public cloud 1905 includes gateway 1940, cloud orchestration module 1941, host physical machine set 1942, virtual machine set 1943, and container set 1944.

Computer 1901 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1930. As is well understood in the art of computer technology, and depending upon the technology, performance of a computer-implemented method may be distributed among multiple computers and/or between multiple locations. On the other hand, in this presentation of computing environment 1900, detailed discussion is focused on a single computer, specifically computer 1901, to keep the presentation as simple as possible. Computer 1901 may be located in a cloud, even though it is not shown in a cloud in FIG. 19. On the other hand, computer 1901 is not required to be in a cloud except to any extent as may be affirmatively indicated.

Processor set 1910 includes one, or more, computer processors of any type now known or to be developed in the future. Processing circuitry 1920 may be distributed over multiple packages, for example, multiple, coordinated integrated circuit chips. Processing circuitry 1920 may implement multiple processor threads and/or multiple processor cores. Cache 1921 is memory that is located in the processor chip package(s) and is typically used for data or code that should be available for rapid access by the threads or cores running on processor set 1910. Cache memories are typically organized into multiple levels depending upon relative proximity to the processing circuitry. Alternatively, some, or all, of the cache for the processor set may be located “off chip.” In some computing environments, processor set 1910 may be designed for working with qubits and performing quantum computing.

Computer readable program instructions are typically loaded onto computer 1901 to cause a series of operational steps to be performed by processor set 1910 of computer 1901 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1921 and the other storage media discussed below. The program instructions, and associated data, are accessed by processor set 1910 to control and direct performance of the inventive methods. In computing environment 1900, at least some of the instructions for performing the inventive methods may be stored in block 1926 in persistent storage 1913.

Communication fabric 1911 is the signal conduction path that allows the various components of computer 1901 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1912 is any type of volatile memory now known or to be developed in the future. Examples include dynamic type random access memory (RAM) or static type RAM. Typically, the volatile memory is characterized by random access, but this is not required unless affirmatively indicated. In computer 1901, the volatile memory 1912 is located in a single package and is internal to computer 1901, but, alternatively or additionally, the volatile memory may be distributed over multiple packages and/or located externally with respect to computer 1901.

Persistent storage 1913 is any form of non-volatile storage for computers that is now known or to be developed in the future. The non-volatility of this storage means that the stored data is maintained regardless of whether power is being supplied to computer 1901 and/or directly to persistent storage 1913. Persistent storage 1913 may be a read-only memory (ROM), but typically at least a portion of the persistent storage allows writing of data, deletion of data and re-writing of data. Some familiar forms of persistent storage include magnetic disks and solid-state storage devices. Operating system 1922 may take several forms, such as various known proprietary operating systems or open-source Portable Operating System Interface type operating systems that employ a kernel. The code included in block 1926 typically includes at least some of the computer code involved in performing the inventive methods.

Peripheral device set 1914 includes the set of peripheral devices of computer 1901. Data communication connections between the peripheral devices and the other components of computer 1901 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1923 may include components such as a display screen, speaker, microphone, wearable devices (such as goggles and smart watches), keyboard, mouse, printer, touchpad, game controllers, and haptic devices. Storage 1924 is external storage, such as an external hard drive, or insertable storage, such as an SD card. Storage 1924 may be persistent and/or volatile. In some embodiments, storage 1924 may take the form of a quantum computing storage device for storing data in the form of qubits. In embodiments where computer 1901 is required to have a large amount of storage (for example, where computer 1901 locally stores and manages a large database) then this storage may be provided by peripheral storage devices designed for storing very large amounts of data, such as a storage area network (SAN) that is shared by multiple, geographically distributed computers. IoT sensor set 1925 is made up of sensors that can be used in Internet of Things applications. For example, one sensor may be a thermometer and another sensor may be a motion detector.

Network module 1915 is the collection of computer software, hardware, and firmware that allows computer 1901 to communicate with other computers through WAN 1902. Network module 1915 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1915 are performed on the same physical hardware device. In other embodiments (for example, embodiments that utilize software-defined networking (SDN)), the control functions and the forwarding functions of network module 1915 are performed on physically separate devices, such that the control functions manage several different network hardware devices. Computer readable program instructions for performing the inventive methods can typically be downloaded to computer 1901 from an external computer or external storage device through a network adapter card or network interface included in network module 1915.

WAN 1902 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1903 is any computer system that is used and controlled by an end user (for example, a customer of an enterprise that operates computer 1901), and may take any of the forms discussed above in connection with computer 1901. EUD 1903 typically receives helpful and useful data from the operations of computer 1901. For example, in a hypothetical case where computer 1901 is designed to provide a recommendation to an end user, this recommendation would typically be communicated from network module 1915 of computer 1901 through WAN 1902 to EUD 1903. In this way, EUD 1903 can display, or otherwise present, the recommendation to an end user. In some embodiments, EUD 1903 may be a client device, such as thin client, heavy client, mainframe computer, desktop computer and so on.

Remote server 1904 is any computer system that serves at least some data and/or functionality to computer 1901. Remote server 1904 may be controlled and used by the same entity that operates computer 1901. Remote server 1904 represents the machine(s) that collect and store helpful and useful data for use by other computers, such as computer 1901. For example, in a hypothetical case where computer 1901 is designed and programmed to provide a recommendation based on historical data, then this historical data may be provided to computer 1901 from remote database 1930 of remote server 1904.

Public cloud 1905 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1905 is performed by the computer hardware and/or software of cloud orchestration module 1941. The computing resources provided by public cloud 1905 are typically implemented by virtual computing environments that run on various computers making up the computers of host physical machine set 1942, which is the universe of physical computers in and/or available to public cloud 1905. The virtual computing environments (VCEs) typically take the form of virtual machines from virtual machine set 1943 and/or containers from container set 1944. It is understood that these VCEs may be stored as images and may be transferred among and between the various physical machine hosts, either as images or after instantiation of the VCE. Cloud orchestration module 1941 manages the transfer and storage of images, deploys new instantiations of VCEs and manages active instantiations of VCE deployments. Gateway 1940 is the collection of computer software, hardware, and firmware that allows public cloud 1905 to communicate through WAN 1902.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1906 is similar to public cloud 1905, except that the computing resources are only available for use by a single enterprise. While private cloud 1906 is depicted as being in communication with WAN 1902, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1905 and private cloud 1906 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
an electro-optic transducer which comprises:
a microwave resonator comprising a first electrode pad and a second electrode pad separated by a gap; and
an optical transmission line comprising:
an optical resonator disposed within the gap between the first electrode pad and the second electrode pad;
a first photonic mirror disposed at a first end of the optical resonator;
a second photonic mirror disposed at a second end of the optical resonator; and
a third photonic mirror disposed in a central region of the optical resonator.

2. The device of claim 1, wherein the microwave resonator comprises an open-ended coplanar microstrip resonator.

3. The device of claim 1, wherein:
the first photonic mirror comprises a partially reflective mirror;
the second photonic mirror comprises a fully reflective mirror; and
the third photonic mirror comprises a partially reflective mirror.

4. The device of claim 1, wherein the first photonic mirror, the second photonic mirror, and the third photonic mirror comprise respective patterns of photonic crystal structures formed in the optical transmission line, the photonic crystal structures comprising at least one of holes, crenulations, and pillar structures.

5. The device of claim 1, wherein the optical resonator comprises a ridge waveguide structure comprising a first lateral extension connected to the first electrode pad, and a second lateral extension connected to the second electrode pad.

6. The device of claim 1, wherein the microwave resonator and the optical resonator have respective physical lengths that are substantially equal.

7. The device of claim 1, wherein:
the electro-optic transducer comprises a triply resonant electro-optic transducer which is configured to generate optical resonant modes for an optical signal and an optical carrier signal, and to generate a microwave resonant mode for a microwave signal; and
the third photonic mirror disposed in the central region of the optical resonator comprises a reflection property that is configured to shift a phase of the optical resonant modes to enable phase matching between the microwave resonant mode and the optical resonant modes.

8. The device of claim 7, wherein the optical transmission line is configured to enable input and output of the optical signal and the optical carrier signal to and from the optical resonator through the first photonic mirror.

9. The device of claim 7, further comprising a second optical transmission line which comprises a directional coupler that is configured to enable input and output of the optical signal and the optical carrier signal to and from the optical resonator.

10. A device, comprising:
an electro-optic transducer which comprises:
a microwave resonator comprising a first electrode pad, a second electrode pad, a third electrode pad, and an inductive element, wherein the second electrode pad and the third electrode pad are aligned to each other, and separated from the first electrode pad by a gap, and the inductive element is connected to and between the second electrode pad and the third electrode pad; and
an optical transmission line comprising:
an optical resonator disposed within the gap between the first electrode pad and the second and third electrode pads;
a first photonic mirror disposed at a first end of the optical resonator;
a second photonic mirror disposed at a second end of the optical resonator; and
a third photonic mirror disposed in a central region of the optical resonator.

11. The device of claim 10, wherein the inductive element has a voltage-tunable inductance or a magnetic flux-tunable inductance.

12. The device of claim 10, wherein the inductive element comprises a direct-current superconducting quantum interference device.

13. The device of claim 10, wherein the inductive element comprises one of a surface mount inductor device, and an integrated planar inductor element.

14. The device of claim 10, wherein:
the first photonic mirror comprises a partially reflective mirror;
the second photonic mirror comprises a fully reflective mirror; and
the third photonic mirror comprises a partially reflective mirror.

15. The device of claim 10, wherein the first photonic mirror, the second photonic mirror, and the third photonic mirror comprise respective patterns of photonic crystal structures formed in the optical transmission line, the photonic crystal structures comprising at least one of holes, crenulations, and pillar structures.

16. The device of claim 10, wherein the optical resonator comprises a ridge waveguide structure comprising a first lateral extension connected to the first electrode pad, and a second lateral extension connected to the second electrode pad, and a third lateral extension connected to the third electrode pad.

17. The device of claim 10, wherein the microwave resonator and the optical resonator have respective physical lengths that are substantially equal.

18. The device of claim 10, wherein:
the electro-optic transducer comprises a triply resonant electro-optic transducer which is configured to generate optical resonant modes for an optical signal and an optical carrier signal, and to generate a microwave resonant mode for a microwave signal; and
the third photonic mirror disposed in the central region of the optical resonator comprises a reflection property that is configured to shift a phase of the optical resonant modes to enable phase matching between the microwave resonant mode and the optical resonant modes.

19. The device of claim 10, further comprising at least one tuning electrode coupled to a portion of the optical resonator, and configured to apply a tuning voltage to the portion of the optical resonator to tune an optical resonant frequency of the optical resonator.

20. A system, comprising;
a quantum processor;
a control system that is configured to control operation of the quantum processor, wherein the control system comprises at least one electro-optic transducer, which comprises:
a microwave resonator comprising a first electrode pad and a second electrode pad separated by a gap; and
an optical transmission line comprising:
an optical resonator disposed within the gap between the first electrode pad and the second electrode pad;
a first photonic mirror disposed at a first end of the optical resonator;
a second photonic mirror disposed at a second end of the optical resonator; and
a third photonic mirror disposed in a central region of the optical resonator;
wherein the at least one electro-optic transducer is configured to (i) convert a microwave signal, which is output from the quantum processor, to an optical signal that is transmitted over an optical communications network, and to (ii) convert an optical signal, which is received from the optical communications network, into a microwave signal that is input to the quantum processor.
